(19) United States
(12) Patent Application Publication
(10) Pub. No.: US 2023/0276641 A1
(43) Pub. Date: Aug. 31, 2023

(54) PHOTOELECTRIC CONVERSION ELEMENT AND IMAGING DEVICE

(71) Applicant: SONY GROUP CORPORATION, TOKYO (JP)

(72) Inventors: AYUMI KAI, TOKYO (JP); YOSUKE SAITO, TOKYO (JP)

(21) Appl. No.: 18/006,569

(22) PCT Filed: Jul. 16, 2021
(86) PCT No.: PCT/JP2021/026730

§ 371 Date: Jan. 23, 2023

(30) Foreign Application Priority Data
Jul. 31, 2020 (JP) 2020-131137

(51) Int. Cl. H10K 39/32; H10K 85/20; H10K 39/38; H10K 39/00; H10K 30/20; H10K 30/85; H10K 30/86

(52) U.S. Cl. CPC H10K 39/32; H10K 85/211; H10K 39/38; H10K 39/601; H10K 30/211; H10K 30/85; H10K 30/86; H10K 2101/30

(57) ABSTRACT

A photoelectric conversion element according to an embodiment of the present disclosure includes: a first electrode; a second electrode disposed to be opposed to the first electrode; and an organic photoelectric conversion layer provided between the first electrode and the second electrode and including a first organic semiconductor material, a second organic semiconductor material, and a third organic semiconductor material. The second organic semiconductor material has a Highest Occupied Molecular Orbital (HOMO) level being deeper than a Lowest Unoccupied Molecular Orbital (LUMO) level of the first organic semiconductor material and having a difference of 1.0 eV or more and 2.0 eV or less from the LUMO level of the first organic semiconductor material. The third organic semiconductor material has a crystalline property and has a linear absorption coefficient of 10000 cm⁻¹ or less in a visible light region and an optical absorption edge wavelength of 550 nm or less.

### TECHNICAL FIELD

The present disclosure relates to a photoelectric conversion element using, for example, an organic material and an imaging device including the photoelectric conversion element.

### BACKGROUND ART

For example, PTL 1 discloses a photoelectric conversion element that achieves an improvement in spectral characteristics, responsiveness, and EQE by providing, between a pair of opposing electrodes, a photoelectric conversion layer including three types of organic semiconductor materials: fullerene or a derivative thereof as a first organic semiconductor material; subphthalocyanine or a derivative thereof as a second organic semiconductor material; and a quinacridone derivative, a triallylamine derivative, or a benzothienobenzothiophene derivative as a third organic semiconductor material.

### CITATION LIST

### Patent Literature

PTL 1: International Publication No. WO2016/194630

### SUMMARY OF THE INVENTION

Incidentally, it is required, for a photoelectric conversion element, to have an improvement in spectral characteristics, electric characteristics, and heat resistance.

It is desirable to provide a photoelectric conversion element and an imaging device that make it possible to improve spectral characteristics, electric characteristics, and heat resistance.

A photoelectric conversion element according to an embodiment of the present disclosure includes: a first electrode; a second electrode disposed to be opposed to the first electrode; and an organic photoelectric conversion layer provided between the first electrode and the second electrode and including a first organic semiconductor material, a second organic semiconductor material, and a third organic semiconductor material, in which the second organic semiconductor material has a Highest Occupied Molecular Orbital (HOMO) level which is deeper than a Lowest Unoccupied Molecular Orbital (LUMO) level of the first organic semiconductor material and which has a difference of 1.0 eV or more and 2.0 eV or less from the LUMO level of the first organic semiconductor material, and the third organic semiconductor material has a crystalline property and has a linear absorption coefficient of 10000 cm⁻¹ or less in a visible light region and an optical absorption edge wavelength of 550 nm or less.

An imaging device according to an embodiment of the present disclosure includes one or multiple photoelectric conversion elements according to an embodiment of the present disclosure for each of multiple pixels.

In the photoelectric conversion element and the imaging device according to an embodiment of the present disclosure, the organic photoelectric conversion layer including three types of organic materials of the first organic semiconductor material, the second organic semiconductor material, and the third organic semiconductor material is provided between the first electrode and the second electrode. Of the three types of organic materials, the second organic semiconductor material has a HOMO level which is deeper than a LUMO level of the first organic semiconductor material and has a difference of 1.0 eV or more and 2.0 eV or less from a HOMO level of the first organic semiconductor material. This reduces absorption on a long wavelength side. In addition, the third organic semiconductor material has a crystalline property and has a linear absorption coefficient of 10000 cm⁻¹ or less in a visible light region and an optical absorption edge wavelength of 550 nm or less. This improves heat resistance, and reduces generation of a dark current as well as absorption of a wavelength other than a selected wavelength by the third organic semiconductor material.

### BRIEF DESCRIPTION OF THE DRAWINGS

FIG. 1 is a schematic cross-sectional view of an example of a configuration of a photoelectric conversion element according to a first embodiment of the present disclosure.

FIG. 2 is a diagram illustrating an example of an energy level of an organic material included in the photoelectric conversion layer illustrated in FIG. 1.

FIG. 3 is a schematic planar view of a configuration of a unit pixel of an imaging element illustrated in FIG. 1.

FIG. 4 is an explanatory schematic cross-sectional view of a method of manufacturing the imaging element illustrated in FIG. 1.

FIG. 5 is a schematic cross-sectional view of a step subsequent to FIG. 4.

FIG. 6 is a schematic cross-sectional view of an example of a configuration of a photoelectric conversion element according to a second embodiment of the present disclosure.

FIG. 7 is a schematic cross-sectional view of an example of a configuration of a photoelectric conversion element according to a third embodiment of the present disclosure.

FIG. 8 is a schematic cross-sectional view of an example of a configuration of a photoelectric conversion element according to a fourth embodiment of the present disclosure.

FIG. 9 is an equivalent circuit diagram of the photoelectric conversion element illustrated in FIG. 8.

FIG. 10 is a schematic view of an arrangement of a lower electrode and transistors constituting a control section of the photoelectric conversion element illustrated in FIG. 8.

FIG. 11 is a timing diagram illustrating an operation example of the photoelectric conversion element illustrated in FIG. 8.

FIG. 12A is a schematic cross-sectional view of an example of a configuration of a photoelectric conversion element according to a fifth embodiment of the present disclosure.

FIG. 12B is a schematic planar view of an example of a pixel configuration of an imaging device including the photoelectric conversion element illustrated in FIG. 12A.

FIG. 13 is a block diagram illustrating an overall configuration of an imaging device including the photoelectric conversion element illustrated in FIG. 1, etc.

FIG. 14 is a functional block diagram illustrating an example of an electronic apparatus using the imaging device illustrated in FIG. 13.

FIG. 15 is a view depicting an example of a schematic configuration of an endoscopic surgery system.

FIG. 16 is a block diagram depicting an example of a functional configuration of a camera head and a camera control unit (CCU).

FIG. 17 is a block diagram depicting an example of schematic configuration of a vehicle control system.

FIG. 18 is a diagram of assistance in explaining an example of installation positions of an outside-vehicle information detecting section and an imaging section.

### MODES FOR CARRYING OUT THE INVENTION

In the following, description is given in detail of embodiments of the present disclosure with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. First Embodiment
(An example of a photoelectric conversion element including a photoelectric conversion layer including a first organic semiconductor material, a second organic semiconductor material having a predetermined HOMO level, and a third organic semiconductor material having a crystalline property)
   1-1. Configuration of Photoelectric Conversion Element
   1-2. Method of Manufacturing Photoelectric Conversion Element
   1-3. Workings and Effects
2. Second Embodiment (An example of a photoelectric conversion element in which two organic photoelectric conversion sections are stacked)
3. Third Embodiment (An example of a photoelectric conversion element in which three organic photoelectric conversion sections are stacked)
4. Fourth Embodiment (An example of a photoelectric conversion element including a lower electrode including multiple electrodes)
5. Fifth Embodiment (An example of a photoelectric conversion element that performs spectroscopy for an inorganic photoelectric conversion section using a color filter)
6. Application Examples
7. Practical Application Examples
8. Example

### 1. First Embodiment

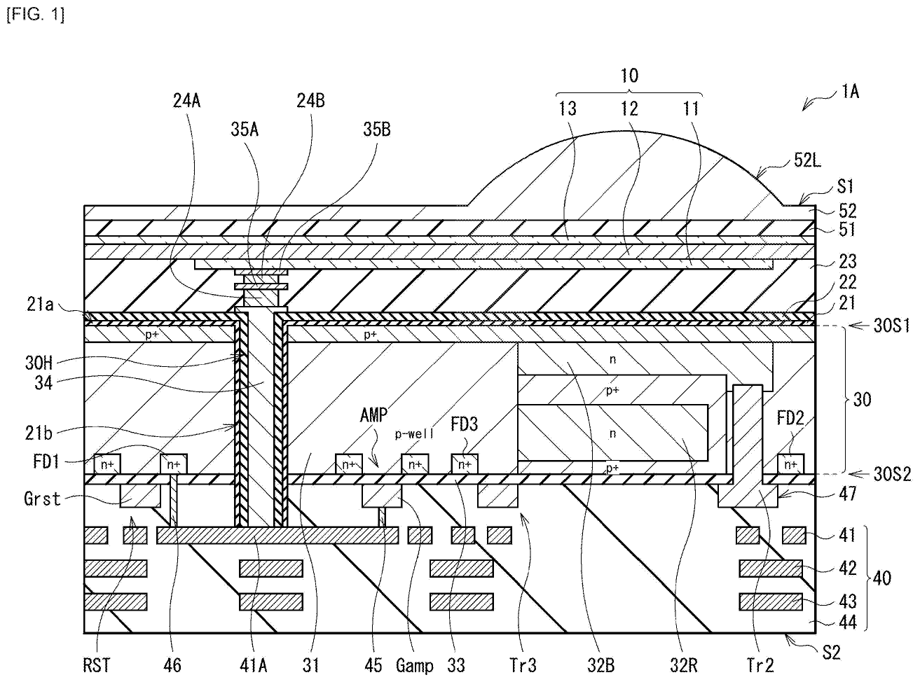

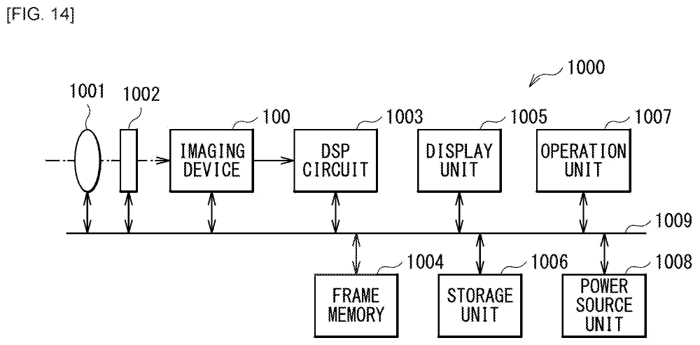

FIG. 1 schematically illustrates an example of a cross-sectional configuration of a photoelectric conversion element (a photoelectric conversion element 1A) according to a first embodiment of the present disclosure. The photoelectric conversion element 1A constitutes one pixel (a unit pixel P) in an imaging device (an imaging device 100, see, e.g., FIG. 13) such as a CMOS (Complementary Metal Oxide Semiconductor) image sensor to be used, for example, in an electronic apparatus such as a digital still camera or a video camera. The photoelectric conversion element 1A includes, for example, an organic photoelectric conversion section 10 in which a lower electrode 11, a photoelectric conversion layer 12, and an upper electrode 13 are stacked in this order. The photoelectric conversion layer 12 is formed using three types of organic materials. In the photoelectric conversion element 1A of the present embodiment, there are used, as the three types of organic materials: a first organic semiconductor material; a second organic semiconductor material having a HOMO level which is deeper than a LUMO level of the first organic semiconductor material and has a difference of 1.0 eV or more and 2.0 eV or less from the LUMO level of the first organic semiconductor material; and a third organic semiconductor material having a crystalline property and having a linear absorption coefficient of 10000 cm⁻¹ or less in a visible light region and an optical absorption edge wavelength of 550 nm or less.

### (1-1. Configuration of Photoelectric Conversion Element)

In the photoelectric conversion element 1A, one organic photoelectric conversion section 10 and two inorganic photoelectric conversion sections 32B and 32R are stacked in a vertical direction for each unit pixel P. The organic photoelectric conversion section 10 is provided on a side of a back surface (a first surface 30A) of a semiconductor substrate 30. The inorganic photoelectric conversion sections 32B and 32R are each formed to be embedded inside the semiconductor substrate 30, and are stacked in a thickness direction of the semiconductor substrate 30.

The organic photoelectric conversion section 10 and the inorganic photoelectric conversion sections 32B and 32R selectively detect light beams of different wavelength bands and perform photoelectric conversion. For example, the organic photoelectric conversion section 10 acquires a color signal of green (G). The inorganic photoelectric conversion sections 32B and 32R acquire color signals of blue (B) and red (R), respectively, depending on differences in absorption coefficients. This enables the photoelectric conversion element 1A to acquire multiple types of color signals in one pixel without using a color filter.

It is to be noted that description is given, for the photoelectric conversion element 1A, of a case of reading holes, of electron-hole pairs generated by photoelectric conversion, as signal charges (a case of adopting a p-type semiconductor region as a photoelectric conversion layer). In addition, in the diagram, “+(plus)” attached to “p” and “n” indicates that p-type or n-type impurity concentration is high.

The semiconductor substrate 30 is configured by, for example, an n-type silicon (Si) substrate, and includes a p-well 31 in a predetermined region. A second surface (a front surface of the semiconductor substrate 30) 30B of the p-well 31 is provided with, for example, various floating diffusions (floating diffusion layers) FD (e.g., FD1, FD2, and FD3), various transistors Tr (e.g., a vertical transistor (transfer transistor) Tr2, a transfer transistor Tr3, an amplifier transistor (modulation element) AMP, a reset transistor RST, and a selection transistor SEL), and a multilayer wiring layer 40. The multilayer wiring layer 40 has a configuration in which, for example, wiring layers 41, 42, and 43 are stacked inside an insulating layer 44. In addition, a peripheral part of the semiconductor substrate 30 is provided with a peripheral circuit (unillustrated) including a logic circuit or the like.

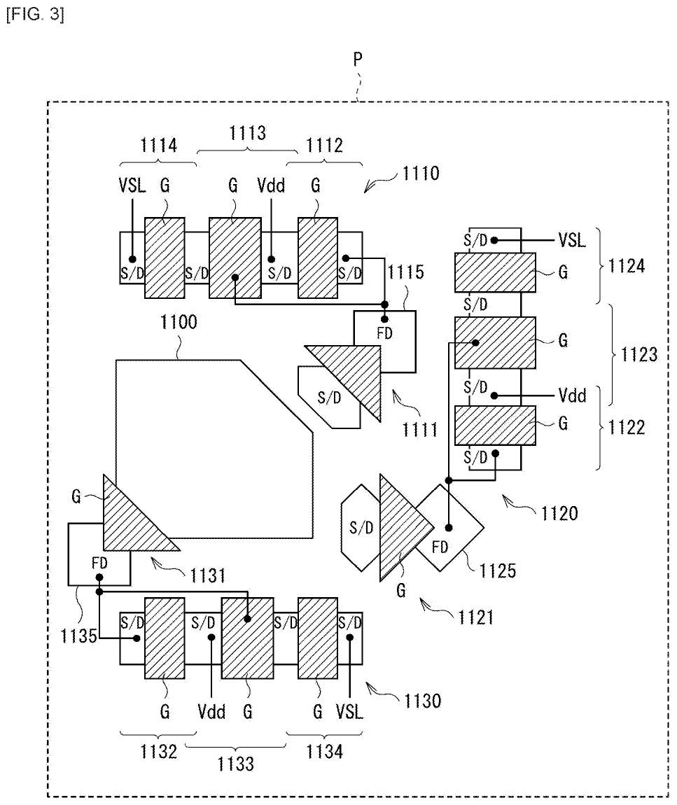

It is to be noted that, in FIG. 3, a side of the first surface 30A of the semiconductor substrate 30 is denoted by a light incident side 51, and a side of the second surface 30B thereof is denoted by a wiring layer side S2.

As described above, the organic photoelectric conversion section 10 has a configuration in which the lower electrode 11, the photoelectric conversion layer 12, and the upper electrode 13 are stacked in this order, and the photoelectric conversion layer 12 has, in the layer, a bulk hetero junction structure. The bulk hetero junction structure is a p/n junction surface formed by mixing a p-type semiconductor and a n-type semiconductor together.

The inorganic photoelectric conversion sections 32B and 32R are configured by, for example, a PIN (Positive Intrinsic Negative) type photodiode, and each thereof has a p-n junction in a predetermined region of the semiconductor substrate 30. The inorganic photoelectric conversion sections 32B and 32R enable spectroscopy on light in the vertical direction by utilizing a difference in wavelength bands to be absorbed depending on incidence depth of light in the silicon substrate.

The inorganic photoelectric conversion section 32B selectively detects blue light and accumulates signal charges corresponding to a blue color; the inorganic photoelectric conversion section 32B is installed at a depth at which the blue light is able to be efficiently subjected to photoelectric conversion. The inorganic photoelectric conversion section 32R selectively detects red light and accumulates signal charges corresponding to a red color; the inorganic photoelectric conversion section 32R is installed at a depth at which the red light is able to be efficiently subjected to photoelectric conversion. It is to be noted that blue (B) is a color corresponding to a wavelength band of 380 nm or more and less than 500 nm, for example, and red (R) is a color corresponding to a wavelength band of 620 nm or more and less than 750 nm, for example. It is sufficient for each of the inorganic photoelectric conversion sections 32B and 32R to be able to detect light of a portion or all of the respective wavelength bands.

Specifically, as illustrated in FIG. 1, each of the inorganic photoelectric conversion section 32B and the inorganic photoelectric conversion section 32R includes, for example, a p+ region serving as a hole accumulation layer and an n region serving as an electron accumulation layer (having a p-n-p stacked structure). The n region of the inorganic photoelectric conversion section 32B is coupled to the vertical transistor Tr2. The p+ region of the inorganic photoelectric conversion section 32B bends along the vertical transistor Tr2, and is linked to the p+ region of the inorganic photoelectric conversion section 32R.

The vertical transistor Tr2 is a transfer transistor that transfers, to the floating diffusion FD2, the signal charges corresponding to the blue color generated and accumulated in the inorganic photoelectric conversion section 32B. The inorganic photoelectric conversion section 32B is formed at a deep position from the second surface 30B of the semiconductor substrate 30, and thus the transfer transistor of the inorganic photoelectric conversion section 32B is preferably configured by the vertical transistor Tr2.

The transfer transistor Tr3 transfers, to the floating diffusion FD3, the signal charges corresponding to the red color generated and accumulated in the inorganic photoelectric conversion section 32R, and is configured by, for example, a MOS transistor.

The amplifier transistor AMP is a modulation element that modulates an amount of electric charges generated in the organic photoelectric conversion section 10, and is configured by, for example, a MOS transistor.

The reset transistor RST resets electric charges transferred from the organic photoelectric conversion section 10 to the floating diffusion FD1, and is configured by, for example, a MOS transistor.

Insulating layers 21 and 22 and an interlayer insulating layer 23 are stacked in this order, for example, from a side of the semiconductor substrate 30 between the first surface 30A of the semiconductor substrate 30 and the lower electrode 11. A protective layer 51 is provided on the upper electrode 13. An on-chip lens layer 52, which configures an on-chip lens 52L and serves also as a planarization layer, is disposed above the protective layer 51.

A through-electrode 34 is provided between the first surface 30A and the second surface 30B of the semiconductor substrate 30. The organic photoelectric conversion section 10 is coupled to a gate Gamp of the amplifier transistor AMP and the floating diffusion FD1 via the through-electrode 34. This makes it possible for the photoelectric conversion element 1A to favorably transfer, as the signal charges, electric charges (holes) generated in the organic photoelectric conversion section 10 on the side of the first surface 30A of the semiconductor substrate 30 to the side of the second surface 30B of the semiconductor substrate 30 via the through-electrode 34, and thus to enhance the characteristics.

The through-electrode 34 is provided for each unit pixel P, for example. The through-electrode 34 functions as a connector between the organic photoelectric conversion section 10 and the gate Gamp of the amplifier transistor AMP as well as the floating diffusion FD1, and serves as a transmission path for electric charges generated in the organic photoelectric conversion section 10.

The lower end of the through-electrode 34 is coupled to, for example, a coupling section 41A in the wiring layer 41, and the coupling section 41A and the gate Gamp of the amplifier transistor AMP are coupled to each other via a lower first contact 45. The coupling section 41A and the floating diffusion FD1 are coupled to the lower electrode 11 via a lower second contact 46. It is to be noted that, in FIG. 1, the through-electrode 34 is illustrated to have a cylindrical shape, but this is not limitative; the through-electrode 34 may also have a tapered shape, for example.

As illustrated in FIG. 3, a reset gate Grst of the reset transistor RST is preferably disposed next to the floating diffusion FD1. This makes it possible to reset electric charges accumulated in the floating diffusion FD1 by the reset transistor RST.

In the organic photoelectric conversion section 10 of the present embodiment, light incident on the photoelectric conversion element 1A from the light incident side S1 is absorbed by the photoelectric conversion layer 12. Excitons thus generated move to an interface between an electron donor and an electron acceptor constituting the photoelectric conversion layer 12, and undergo exciton separation, i.e., dissociate into electrons and holes. The electric charges (electrons and holes) generated here are transported to different electrodes by diffusion due to a difference in carrier concentrations or by an internal electric field due to a difference in work functions between an anode (here, the lower electrode 11) and a cathode (here, the upper electrode 13), and are detected as a photocurrent. In addition, application of a potential between the lower electrode 11 and the upper electrode 13 makes it possible to control directions in which electrons and holes are transported.

In the following, description is given of configurations, materials, and the like of the respective sections constituting the photoelectric conversion element 1A.

The organic photoelectric conversion section 10 absorbs light corresponding to a portion or all of selective wavelength bands (a visible light region of 480 nm or more and less than 620 nm) to generate excitons (electron-hole pairs). In the imaging device 100 described later, for example, holes, of the electron-hole pairs generated by photoelectric conversion, are read as signal charges from a side of the lower electrode 11. In the photoelectric conversion element 1A, the lower electrode 11 is formed separately for each unit pixel P, for example. The photoelectric conversion layer 12 and the upper electrode 13 are provided as successive layers common to multiple unit pixels P (e.g., a pixel section 100A illustrated in FIG. 13).

The lower electrode 11 is configured by, for example, a light transmissive electrically-conductive film. Examples of a constituent material of the lower electrode 11 include indium tin oxide (ITO), In₂O₃ doped with tin (Sn) as a dopant, indium tin oxides including crystalline ITO and amorphous ITO. As a constituent material of the lower electrode 11, a tin oxide (SnO₂)-based material doped with a dopant or a zinc oxide-based material doped with a dopant may be used, in addition to those described above. Examples of the zinc oxide-based material include aluminum zinc oxide (AZO) doped with aluminum (Al) as a dopant, gallium zinc oxide (GZO) doped with gallium (Ga), boron zinc oxide doped with boron (B), and indium zinc oxide (IZO) doped with indium (In). In addition, CuI, InSbO₄, ZnMgO, CuInO₂, MgIN₂O₄, CdO, ZnSnO₃, TiO₂, or the like may be used as a constituent material of the lower electrode 11. Further, a spinel-type oxide or an oxide having a YbFe₂O₄ structure may be used. It is to be noted that the lower electrode 11 formed using the material as described above typically has a high work function, and functions as an anode electrode.

The photoelectric conversion layer 12 converts optical energy into electric energy. The photoelectric conversion layer 12 absorbs light of a portion or all of wavelengths in a range of a visible light region of 480 nm or more and less than 620 nm, for example. The photoelectric conversion layer 12 includes at least a p-type semiconductor and an n-type semiconductor, and a junction surface (p/n junction surface) between the p-type semiconductor and the n-type semiconductor is formed in the layer. The n-type semiconductor is an electron-transporting material that functions relatively as an electron acceptor (acceptor), and the p-type semiconductor is a hole-transporting material that functions relatively as an electron donor (donor). The photoelectric conversion layer 12 provides a field in which excitons (electron-hole pairs) generated upon light absorption are separated into electrons and holes; specifically, excitons are separated into electrons and holes at an interface (p/n junction surface) between the electron donor and the electron acceptor.

As described above, the photoelectric conversion layer 12 of the present embodiment includes three types of organic materials of the first organic semiconductor material, the second organic semiconductor material, and the third organic semiconductor material.

The first organic semiconductor material is, for example, an organic material that functions as an n-type semiconductor. The second organic semiconductor material is an organic material, or a so-called dye material, that photoelectrically converts light of a predetermined wavelength band, while transmitting light of another wavelength band. The third organic semiconductor material is, for example, an organic material that functions as a p-type semiconductor. Each of the first organic semiconductor material, the second organic semiconductor material, and the third organic semiconductor material is a low-molecular compound having a molecular weight of 2000 or less; specific examples thereof include the following organic materials.

Examples of the first organic semiconductor material include C₆₀ fullerene, C₇₀ fullerene, and derivatives thereof.

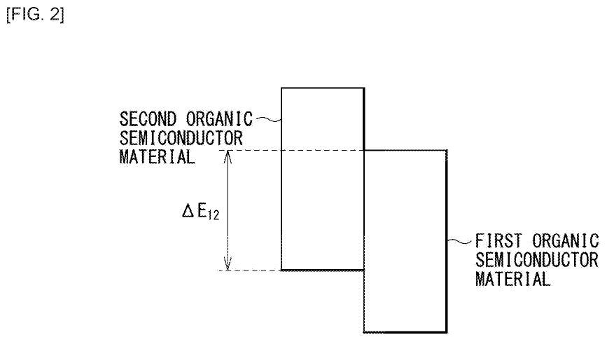

For example, as illustrated in FIG. 2, the second organic semiconductor material has an HOMO level which is deeper than a LUMO level of the first organic semiconductor material and has a difference (ΔE₁₂) of 1.0 eV or more and 2.0 eV or less from the LUMO level of the first organic semiconductor material. Specific examples thereof include a donor-acceptor dye material having a local maximum absorption at a wavelength band of 380 nm or more and 750 nm or less, for example. More specific examples of the second organic semiconductor material include a so-called DπA compound having, in the molecule, a donor site, a π-electron conjugated site, and an acceptor site.

Examples of the third organic semiconductor material include an organic material having a crystalline property and having a linear absorption coefficient of 10000 cm⁻¹ or less in a visible light region and an optical absorption edge wavelength of 550 nm or less.

The photoelectric conversion layer 12 has a thickness of, for example, 25 nm or more and 400 nm or less, preferably 50 nm or more and 350 nm or less, and more preferably 150 nm or more and 300 nm or less.

It is to be noted that the photoelectric conversion layer 12 may include an organic material other than the materials described above.

The upper electrode 13 is configured by a light transmissive electrically-conductive film, similarly to the lower electrode 11. In the photoelectric conversion element 1A using the organic photoelectric conversion section 10 as one pixel (unit pixel P), the upper electrode 13 may be separated for each of the pixels, or may be formed as an electrode common to the pixels. The upper electrode 13 has a thickness of, for example, 10 nm to 200 nm.

It is to be noted that another layer may be further provided between the photoelectric conversion layer 12 and the lower electrode 11, and between the photoelectric conversion layer 12 and the upper electrode 13. For example, an underlying layer, a hole transport layer, an electron blocking layer, and the like may be provided between the lower electrode 11 and the photoelectric conversion layer 12. A hole blocking layer, a work function adjusting layer, an electron transport layer, and the like may be provided between the photoelectric conversion layer 12 and the upper electrode 13.

The insulating layer 21 may be a film having a positive fixed charge or a film having a negative fixed charge. Examples of a material of the film having a negative fixed charge include hafnium oxide (HfO₂), aluminum oxide (Al₂O₃), zirconium oxide (ZrO₂), tantalum oxide (Ta₂O₅), and titanium oxide (TiO₂). In addition, as a material other than those described above, there may be used lanthanum oxide, praseodymium oxide, cerium oxide, neodymium oxide, promethium oxide, samarium oxide, europium oxide, gadolinium oxide, terbium oxide, dysprosium oxide, holmium oxide, thulium oxide, ytterbium oxide, lutetium oxide, yttrium oxide, an aluminum nitride film, a hafnium oxynitride film, an aluminum oxynitride film, or the like.

The insulating layer 21 may have a configuration in which two or more types of films are stacked. This makes it possible to further enhance a function as the hole accumulation layer, for example, in a case of the film having a negative fixed charge.

A material of the insulating layer 22 is not particularly limited, and the insulating layer 22 is formed by, for example, silicon oxide (SiOₓ), TEOS, silicon nitride (SiNₓ), silicon oxynitride (SiOₓN_{y}), or the like.

For example, the interlayer insulating layer 23 is configured by a monolayer film of one of silicon oxide (SiOₓ), silicon nitride (SiNₓ), silicon oxynitride (SiOₓN_{y}), or the like, or alternatively is configured by a stacked film of two or more thereof.

A lower first contact 45, a lower second contact 46, an upper first contact 24A, a pad section 35A, an upper second contact 24B, and a pad section 35B are each configured by a doped silicon material such as PDAS (Phosphorus Doped Amorphous Silicon), or a metal material such as aluminum (Al), tungsten (W), titanium (Ti), cobalt (Co), hafnium (Hf), or tantalum (Ta), for example.

The protective layer 51 is configured by a light-transmissive material, and is configured by, for example, a monolayer film of one of silicon oxide (SiOₓ), silicon nitride (SiNₓ), silicon oxynitride (SiOₓN_{y}), or the like, or alternatively is configured by a stacked film of two or more thereof. The protective layer 51 has a thickness of, for example, 100 nm to 30000 nm.

The on-chip lens layer 52 is formed on the protective layer 51 to cover the entire surface thereof. Multiple on-chip lenses (microlenses) 52L are provided on a front surface of the on-chip lens layer 52. The on-chip lens 52L condenses light incident from above on respective light-receiving surfaces of the organic photoelectric conversion section 10 and the inorganic photoelectric conversion sections 32B and 32R. In the present embodiment, the multilayer wiring layer 40 is formed on the side of the second surface 30B of the semiconductor substrate 30. This enables the respective light-receiving surfaces of the organic photoelectric conversion section 10 and the inorganic photoelectric conversion sections 32B and 32R to be arranged close to each other, thus making it possible to reduce variations in sensitivities between colors generated depending on a F-value of the on-chip lens 52L.

FIG. 3 is a plan view of a configuration example of the photoelectric conversion element 1A in which multiple photoelectric conversion sections (e.g., organic photoelectric conversion section 10 and inorganic photoelectric conversion sections 32B and 32R described above) are stacked to which the technology according to the present disclosure is applicable. That is, FIG. 3 illustrates an example of a planar configuration of the unit pixel P constituting the pixel section 100A illustrated in FIG. 13, for example.

The unit pixel P includes a photoelectric conversion region 1100 in which a red photoelectric conversion section (inorganic photoelectric conversion section 32R in FIG. 1), a blue photoelectric conversion section (inorganic photoelectric conversion section 32B in FIG. 1), and a green photoelectric conversion section (organic photoelectric conversion section 10 in FIG. 1) (neither of which is illustrated in FIG. 3) that perform photoelectric conversion of light beams of respective wavelengths of R (Red), G (Green), and B (Blue) are stacked in three layers in the order of the green photoelectric conversion section, the blue photoelectric conversion section, and the red photoelectric conversion section, for example, from a side of the light-receiving surface (light incident side S1 in FIG. 1). Further, the unit pixel P includes a Tr group 1110, a Tr group 1120, and a Tr group 1130 as charge readout sections that read electric charges corresponding to light beams of the respective wavelengths of R, G, and B from the red photoelectric conversion section, the green photoelectric conversion section, and the blue photoelectric conversion section. The organic photoelectric conversion section 10 performs, in one unit pixel P, spectroscopy in the vertical direction, i.e., spectroscopy of light beams of R, G, and B in respective layers as the red photoelectric conversion section, the green photoelectric conversion section, and the blue photoelectric conversion section stacked in the photoelectric conversion region 1100.

The Tr group 1110, the Tr group 1120, and the Tr group 1130 are formed on the periphery of the photoelectric conversion region 1100. The Tr group 1110 outputs, as a pixel signal, a signal charge corresponding to light of R generated and accumulated in the red photoelectric conversion section. The Tr group 1110 is configured by a transfer Tr (MOS FET) 1111, a reset Tr 1112, an amplification Tr 1113, and a selection Tr 1114. The Tr group 1120 outputs, as a pixel signal, a signal charge corresponding to light of B generated and accumulated in the blue photoelectric conversion section. The Tr group 1120 is configured by a transfer Tr 1121, a reset Tr 1122, an amplification Tr 1123, and a selection Tr 1124. The Tr group 1130 outputs, as a pixel signal, a signal charge corresponding to light of G generated and accumulated in the green photoelectric conversion section. The Tr group 1130 includes a transfer Tr 1131, a reset Tr 1132, an amplification Tr 1133, and a selection Tr 1134.

The transfer Tr 1111 is configured by a gate G, a source/drain region S/D, and an FD (floating diffusion) 1115 (constituting source/drain region). The transfer Tr 1121 is configured by a gate G, a source/drain region S/D, and an FD 1125. The transfer Tr 1131 is configured by a gate G, (a source/drain region S/D coupled to) the green photoelectric conversion section of the photoelectric conversion region 1100, and an FD 1135. It is to be noted that the source/drain region of the transfer Tr 1111 is coupled to the red photoelectric conversion section of the photoelectric conversion region 1100, and that the source/drain region S/D of the transfer Tr 1121 is coupled to the blue photoelectric conversion section of the photoelectric conversion region 1100.

Each of the reset Trs 1112, 1122, and 1132, the amplification Trs 1113, 1123, and 1133, and the selection Trs 1114, 1124, and 1134 is configured by a gate G and a pair of source/drain regions S/D arranged to interpose the gate G therebetween.

The FDs 1115, 1125, and 1135 are coupled to the source/drain regions S/D serving as sources of the reset Trs 1112, 1122, and 1132, respectively, and are coupled to the gates G of the amplification Trs 1113, 1123, and 1133, respectively. A power source Vdd is coupled to the common source/drain regions S/D in each of the reset Tr 1112 and the amplification Tr 1113, the reset Tr 1132 and the amplification Tr 1133, and the reset Tr 1122 and the amplification Tr 1123. A VSL (vertical signal line) is coupled to each of the source/drain regions S/D serving as the sources of the selection Trs 1114, 1124, and 1134.

### (1-2. Method of Manufacturing Photoelectric Conversion Element)

The photoelectric conversion element 1A illustrated in FIG. 1 may be manufactured, for example, as follows.

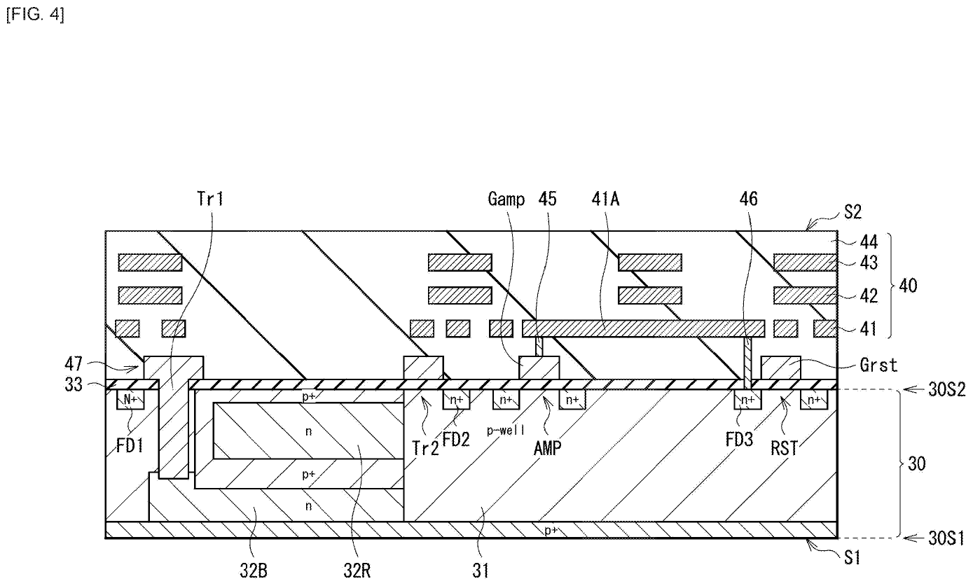

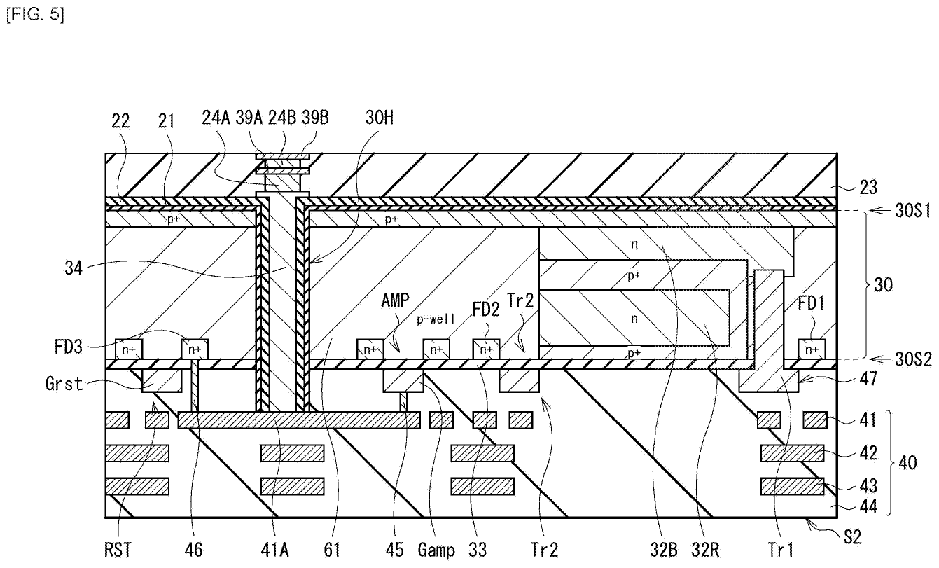

FIGS. 4 and 5 illustrate the method of manufacturing the photoelectric conversion element 1A in the order of steps. First, as illustrated in FIG. 4, the p-well 31, for example, is formed as a well of a first electrically-conductivity type inside the semiconductor substrate 30, and the inorganic photoelectric conversion sections 32B and 32R of a second electrically-conductivity type (e.g., n-type) is formed inside the p-well 31. The p+ region is formed in the vicinity of the first surface 30A of the semiconductor substrate 30.

As illustrated in FIG. 4 as well, on the second surface 30B of the semiconductor substrate 30, n+ regions serving as the floating diffusions FD1 to FD3 are formed, and then, a gate insulating layer 33 and a gate wiring layer 47 including respective gates of the vertical transistor Tr2, the transfer transistor Tr3, the amplifier transistor AMP, and the reset transistor RST are formed. This allows for formation of the vertical transistor Tr2, the transfer transistor Tr3, the amplifier transistor AMP, and the reset transistor RST. Further, the multilayer wiring layer 40 that includes the lower first contact 45, the lower second contact 46, the wiring layers 41 including the coupling section 41A, 43, and 43, and the insulating layer 44 is formed on the second surface 30B of the semiconductor substrate 30.

As a base of the semiconductor substrate 30, for example, an SOI (Silicon on Insulator) substrate is used, in which the semiconductor substrate 30, an embedded oxide film (unillustrated), and a holding substrate (unillustrated) are stacked. Although not illustrated in FIG. 4, the embedded oxide film and the holding substrate are joined to the first surface 30A of the semiconductor substrate 30.

Next, a supporting substrate (unillustrated) or another semiconductor substrate, etc. is joined to the side of the second surface 30B (side of the multilayer wiring layer 40) of the semiconductor substrate 30, and the substrate is turned upside down. Subsequently, the semiconductor substrate 30 is separated from the embedded oxide film and the holding substrate of the SOI substrate to expose the first surface 30A of the semiconductor substrate 30. The above steps may be performed by techniques used in common CMOS processes such as ion implantation and CVD (Chemical Vapor Deposition).

Next, as illustrated in FIG. 5, the semiconductor substrate 30 is worked from the side of the first surface 30A by dry-etching, for example, to form a ring-shaped through-hole 30H. As illustrated in FIG. 5, as for the depth, the through-hole 30H penetrates from the first surface 30A to the second surface 30B of the semiconductor substrate 30, and reaches, for example, the coupling section 41A.

Subsequently, as illustrated in FIG. 5, for example, the insulating layer 21 is formed on the first surface 30A of the semiconductor substrate 30 and a side surface of the through-hole 30H. Two or more types of films may be stacked as the insulating layer 21. This makes it possible to further enhance the function as the hole accumulation layer. After the insulating layer 21 is formed, the insulating layer 22 is formed.

Next, an electric conductor is buried in the through-hole 30H to form the through-electrode 34. It may be possible to use, as the electric conductor, for example, a metal material such as aluminum (Al), tungsten (W), titanium (Ti), cobalt (Co), hafnium (Hf), and tantalum (Ta), in addition to a doped silicon material such as PDAS (Phosphorus Doped Amorphous Silicon).

Subsequently, on the insulating layer 22 and the through-electrode 34, the interlayer insulating layer 23 is formed in which the upper first contact 24A, the pad section 35A, the upper second contact 24B, and the pad section 35B electrically coupling the lower electrode 11 and the through-electrode 34 together are provided on the through-electrode 34.

Thereafter, the lower electrode 11, the photoelectric conversion layer 12, the upper electrode 13, and the protective layer 51 are formed in this order on the interlayer insulating layer 23. The photoelectric conversion layer 12 is formed, for example, by means of a vapor deposition method, for example. Finally, there is disposed the on-chip lens layer 52 including on the surface the multiple on-chip lenses 52L. Thus, the photoelectric conversion element 1A illustrated in FIG. 1 is completed.

It is to be noted that the method of forming the photoelectric conversion layer 12 is not necessarily limited to the method using a vacuum deposition method; another method, for example, a spin-coating technique, a printing technique, or the like may be used.

In the photoelectric conversion element 1A, when light is incident on the organic photoelectric conversion section 10 via the on-chip lens 52L, the light passes through the organic photoelectric conversion section 10, the inorganic photoelectric conversion sections 32B and the 32R in this order, and is subjected to photoelectric conversion for each color light beam of green (G), blue (B), and red (R) in the passing process. Hereinafter, description is given of a signal acquisition operation of each color.

### (Acquisition of Green Signal by Organic Photoelectric Conversion Section 10)

Green light, of the light incident on the photoelectric conversion element 1A, is first selectively detected (absorbed) by the organic photoelectric conversion section 10 and is subjected to photoelectric conversion.

The organic photoelectric conversion section 10 is coupled to the gate Gamp of the amplifier transistor AMP and the floating diffusion FD1 via the through-electrode 34. Accordingly, holes of the electron-hole pairs generated in the organic photoelectric conversion section 10 are extracted from the side of the lower electrode 11, transferred to the side of the second surface 30B of the semiconductor substrate 30 via the through-electrode 34, and accumulated in the floating diffusion FD1. At the same time, a charge amount generated in the organic photoelectric conversion section 10 is modulated into a voltage by the amplifier transistor AMP.

In addition, the reset gate Grst of the reset transistor RST is disposed next to the floating diffusion FD1. As a result, the electric charges accumulated in the floating diffusion FD1 are reset by the reset transistor RST.

Here, the organic photoelectric conversion section 10 is coupled not only to the amplifier transistor AMP but also to the floating diffusion FD1 via the through-electrode 34, thus making it possible to easily reset the electric charges accumulated in the floating diffusion FD1 by the reset transistor RST.

On the other hand, in a case where the through-electrode 34 and the floating diffusion FD1 are not coupled to each other, it is difficult to reset the electric charges accumulated in the floating diffusion FD1, thus resulting in application of a large voltage to pull out the electric charges to the side of the upper electrode 13. Accordingly, there is a possibility that the photoelectric conversion layer 12 may be damaged. In addition, the structure that enables resetting in a short period of time leads to an increase in dark noises, resulting in a trade-off, which structure is thus difficult.

### (Acquisition of Blue Signal and Red Signal by Inorganic Photoelectric Conversion Sections 32B and 32R)

Subsequently, of the light transmitted through the organic photoelectric conversion section 10, blue light and red light are sequentially absorbed by the inorganic photoelectric conversion section 32B and the inorganic photoelectric conversion section 32R, respectively, and are subjected to photoelectric conversion. In the inorganic photoelectric conversion section 32B, electrons corresponding to the incident blue light are accumulated in an n region of the inorganic photoelectric conversion section 32B, and the accumulated electrons are transferred to the floating diffusion FD2 by the vertical transistor Tr2. Similarly, in the inorganic photoelectric conversion section 32R, electrons corresponding to the incident red light are accumulated in an n region of the inorganic photoelectric conversion section 32R, and the accumulated electrons are transferred to the floating diffusion FD3 by the transfer transistor Tr3.

### (1-3. Workings and Effects)

In the photoelectric conversion element 1A of the present embodiment, the photoelectric conversion layer 12 is provided using the first organic semiconductor material; the second organic semiconductor material having a HOMO level which is deeper than a LUMO level of the first organic semiconductor material and has a difference of 1.0 eV or more and 2.0 eV or less from the LUMO level of the first organic semiconductor material; and the third organic semiconductor material having a crystalline property and having a linear absorption coefficient of 10000 cm⁻¹ or less in a visible light region and an optical absorption edge wavelength of 550 nm or less. This allows for reduction in absorption of a wavelength other than a selected wavelength as well as generation of a dark current. In addition, heat resistance is improved. This is described below.

As for CCD (Charge Coupled Device) image sensors, CMOS image sensors, and the like, an image sensor using an organic photoelectric conversion film has been developed. For example, there has been reported an organic-film-stacked imaging element in which organic films absorbing only specific wavelengths corresponding to three primary colors (RGB) of light are stacked as the photoelectric conversion layer.

However, due to a width of light absorption of a typical organic film, light other than that of a desired wavelength also results in being photoelectrically converted, causing color reproducibility to be deteriorated, which is an issue. Therefore, wavelength selectivity is required to be improved.

In contrast, in the present embodiment, the photoelectric conversion layer 12, which includes three the types of organic materials of the first organic semiconductor material, the second organic semiconductor material, and the third organic semiconductor material, is provided between the lower electrode 11 and the upper electrode 13. Of the three types of organic materials, the second organic semiconductor material has a HOMO level which is deeper than a LUMO level of the first organic semiconductor material and has a difference of 1.0 eV or more and 2.0 eV or less from the LUMO level of the first organic semiconductor material. This increases a gap width between the donor and the acceptor, thus allowing for reduction in the absorption of a long wavelength band. In addition, the third organic semiconductor material has a crystalline property. Accordingly, a structural change due to heat is less likely to occur, thus improving heat resistance. Further, inside the photoelectric conversion layer 12, the area of contact between the third organic semiconductor material and each of the first organic semiconductor material and the second organic semiconductor material becomes small, thus reducing the generation of a dark current. In addition, the third organic semiconductor material has a linear absorption coefficient of 10000 cm⁻¹ or less in a visible light region and an optical absorption edge wavelength of 550 nm or less. This allows for reduction in the absorption of a wavelength other than a selected wavelength by the third organic semiconductor material.

As described above, it is possible, in the photoelectric conversion element 1A of the present embodiment, to improve spectral characteristics, electric characteristics, and heat resistance.

Next, description is given of second to fifth embodiments of the present disclosure. Hereinafter, components similar to those of the first embodiment are denoted by the same reference numerals, and descriptions thereof are omitted as appropriate.

### 2. Second Embodiment

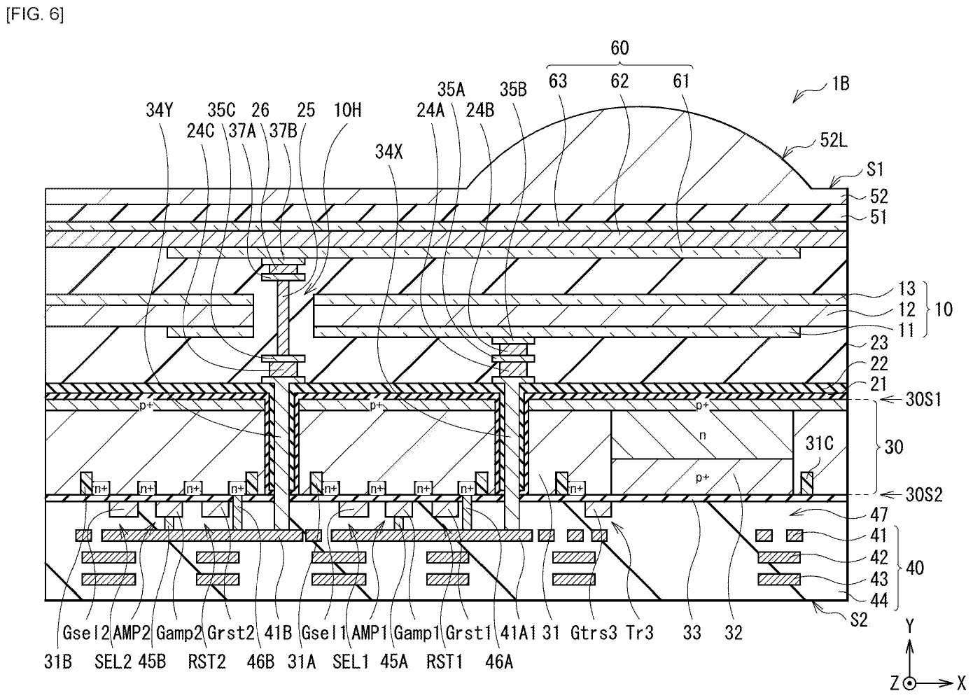

FIG. 6 schematically illustrates an example of a cross-sectional configuration of a photoelectric conversion element (a photoelectric conversion element 1B) according to a second embodiment of the present disclosure. The photoelectric conversion element 1B of the present embodiment differs from the foregoing first embodiment in that two organic photoelectric conversion sections 10 as well as an organic photoelectric conversion section 60 and one inorganic photoelectric conversion section 32 are stacked in a vertical direction.

The organic photoelectric conversion sections 10 and 60 and the inorganic photoelectric conversion section 32 selectively detect light beams of different wavelength bands and perform photoelectric conversion. Specifically, for example, the organic photoelectric conversion section 10 acquires a color signal of green (G) similarly to the foregoing first embodiment. The organic photoelectric conversion section 60 acquires, for example, a color signal of blue (B). The inorganic photoelectric conversion section 32 acquires, for example, a color signals of red (R). This enables the photoelectric conversion element 1B to acquire multiple types of color signals in one pixel without using a color filter.

The organic photoelectric conversion section 60 is stacked above the organic photoelectric conversion section 10, for example, and has a configuration in which the lower electrode 61, the photoelectric conversion layer 62, and the upper electrode 63 are stacked in this order from the side of the first surface 30A of the semiconductor substrate 30, similarly to the organic photoelectric conversion section 10.

The photoelectric conversion layer 62 converts optical energy into electric energy, and includes the above-described three types of organic materials of the first organic semiconductor material, the second organic semiconductor material, and the third organic semiconductor material, similarly to the photoelectric conversion layer 12.

Two through-electrodes 34X and 34Y are provided between the first surface 30A and the second surface 30B of the semiconductor substrate 30.

Similarly to through-electrode 34 of the foregoing first embodiment, the through-electrode 34X is electrically coupled to the lower electrode 11 of the organic photoelectric conversion section 10. Specifically, an upper end of the through-electrode 34X is coupled to the lower electrode 11 via the upper first contact 24A, the pad section 35A, the upper second contact 24B, and the pad section 35B, for example. The lower end of the through-electrode 34X is coupled to each of a gate Gamp1 of an amplifier transistor AMP1 and one source/drain region of a reset transistor RST1 (a reset transistor Tr1rst) serving also as the floating diffusion FD1, via a coupling section 41A1, e.g., in the wiring layer 41, a lower first contact 45A, and a lower second contact 46A.

The through-electrode 34Y is electrically coupled to the lower electrode 61 of the organic photoelectric conversion section 60, and the organic photoelectric conversion section 60 is coupled, via the through-electrode 34Y, to a gate Gamp2 of an amplifier transistor AMP2 and to one source/drain region of a reset transistor RST2 (a reset transistor Tr2rst) serving also as the floating diffusion FD2. The upper end of the through-electrode 34Y is coupled to the lower electrode 61 via, for example, an upper third contact 24C, a pad section 35C, an upper fourth contact 25, a pad section 37A, an upper fifth contact 26, and a pad section 37B.

As described above, the photoelectric conversion element 1B of the present embodiment has a configuration in which the two organic photoelectric conversion sections 10 and 60 and the one inorganic photoelectric conversion section 32 are stacked. It is also possible, in such a configuration, to obtain effects similar to those of the foregoing first embodiment.

### 3. Third Embodiment

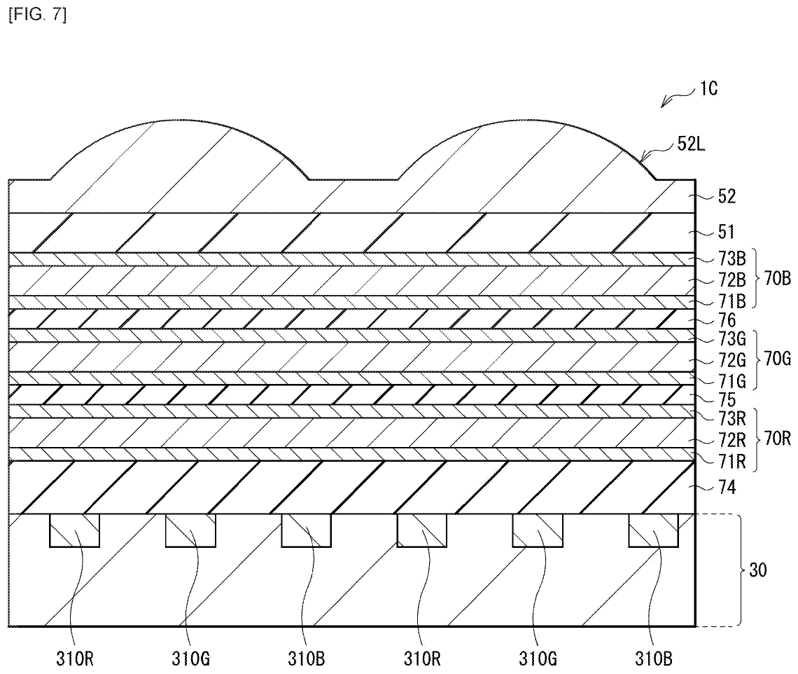

FIG. 7 schematically illustrates an example of a cross-sectional configuration of a photoelectric conversion element (a photoelectric conversion element 1C) according to a third embodiment of the present disclosure. Similarly to the photoelectric conversion element 1A described above, for example, the photoelectric conversion element 1C constitutes one unit pixel P in the imaging device 100 such as a CMOS image sensor that is able to capture an image obtained from visible light, for example, without using a color filter. The photoelectric conversion element 1C of the present embodiment has a configuration in which a red photoelectric conversion section 70R, a green photoelectric conversion section 70G, and a blue photoelectric conversion section 70B are stacked in this order on the semiconductor substrate 30 with an insulating layer 74 interposed therebetween.

The red photoelectric conversion section 70R, the green photoelectric conversion section 70G, and the blue photoelectric conversion section 70B include, respectively, organic photoelectric conversion layers 72R, 72G, and 72B between respective pairs of electrodes, specifically, between a lower electrode 71R and an upper electrode 73R, between a lower electrode 71G and an upper electrode 73G, and between a lower electrode 71B and an upper electrode 73B, respectively.

The on-chip lens layer 52 including the on-chip lens 52L is provided over the blue photoelectric conversion section 70B with the protective layer 51 interposed therebetween. A red electricity storage layer 310R, a green electricity storage layer 310G, and a blue electricity storage layer 310B are provided inside the semiconductor substrate 30. Light incident on the on-chip lens 52L is photoelectrically converted by the red photoelectric conversion section 70R, the green photoelectric conversion section 70G, and the blue photoelectric conversion section 70B, and respective signal charges are sent from the red photoelectric conversion section 70R to the red electricity storage layer 310R, from the green photoelectric conversion section 70G to the green electricity storage layer 310G, and from the blue photoelectric conversion section 70B to the blue electricity storage layer 310B. The signal charges may be either electrons or holes generated by photoelectric conversion; hereinafter, description is given by exemplifying a case where electrons are read as the signal charges.

The semiconductor substrate 30 is configured by, for example, a p-type silicon substrate. The red electricity storage layer 310R, the green electricity storage layer 310G, and the blue electricity storage layer 310B provided in the semiconductor substrate 30 each include the n-type semiconductor region, and the signal charges (electrons) supplied from the red photoelectric conversion section 70R, the green photoelectric conversion section 70G, and the blue photoelectric conversion section 70B are accumulated in the n-type semiconductor region. The n-type semiconductor region of the red electricity storage layer 310R, the green electricity storage layer 310G, and the blue electricity storage layer 310B is formed, for example, by doping the semiconductor substrate 30 with n-type impurities such as phosphorus (P) or arsenic (As). It is to be noted that the semiconductor substrate 30 may be provided on a support substrate (unillustrated) including glass or the like.

The semiconductor substrate 30 is further provided with a pixel transistor for reading electrons from each of the red electricity storage layer 310R, the green electricity storage layer 310G, and the blue electricity storage layer 310B and transferring them, for example, to a vertical signal line (a vertical signal line Lsig in FIG. 13). A floating diffusion of this pixel transistor is provided inside the semiconductor substrate 30, and the floating diffusion is coupled to the red electricity storage layer 310R, the green electricity storage layer 310G, and the blue electricity storage layer 310B. The floating diffusion is configured by the n-type semiconductor region.

The insulating layer 74 is configured by, for example, silicon oxide (SiOₓ), silicon nitride (SiNₓ), silicon oxynitride (SiON), hafnium oxide (HfOₓ), or the like. Multiple types of insulating films may be stacked to constitute the insulating layer 74. The insulating layer 74 may be configured by an organic insulating material. The insulating layer 74 is provided with respective plugs and electrodes for coupling the red electricity storage layer 310R and the red photoelectric conversion section 70R together, the green electricity storage layer 310G and the green photoelectric conversion section 70G together, and the blue electricity storage layer 310B and the blue photoelectric conversion section 70B together.

The red photoelectric conversion section 70R includes the lower electrode 71R, the organic photoelectric conversion layer 72R, and the upper electrode 73R in this order from a position close to the semiconductor substrate 30. The green photoelectric conversion section 70G includes the lower electrode 71G, the organic photoelectric conversion layer 72G, and the upper electrode 73G in this order from a position close to the red photoelectric conversion section 70R. The blue photoelectric conversion section 70B includes the lower electrode 71B, the organic photoelectric conversion layer 72B, and the upper electrode 73B in this order from a position close to the green photoelectric conversion section 70G. The insulating layer 44 is provided between the red photoelectric conversion section 70R and the green photoelectric conversion section 70G, and an insulating layer 76 is provided between the green photoelectric conversion section 70G and the blue photoelectric conversion section 70B. The red photoelectric conversion section 70R selectively absorbs red light (e.g., a wavelength of 620 nm or more and less than 750 nm); the green photoelectric conversion section 70G selectively absorbs green light (e.g., a wavelength of 480 nm or more and less than 620 nm); and the blue photoelectric conversion section 70B selectively absorbs blue light (e.g., a wavelength of 380 nm or more and less than 480 nm) to generate electron-hole pairs.

The lower electrode 71R extracts signal charges generated in the organic photoelectric conversion layer 72R; the lower electrode 71G extracts signal charges generated in the organic photoelectric conversion layer 72G; and the lower electrode 71B extracts signal charges generated in the organic photoelectric conversion layer 72B. The lower electrodes 71R, 71G, and 71B are provided for each pixel, for example. The lower electrodes 71R, 71G, and 71B are each configured by, for example, a light-transmissive electrically-conductive material, specifically, ITO. The lower electrodes 71R, 71G, and 71B may each be configured by, for example, a tin oxide-based material or a zinc oxide-based material. The tin oxide-based material is a material in which tin oxide is doped with a dopant. The zinc oxide-based material is, for example, an aluminum zinc oxide in which zinc oxide is doped with aluminum as a dopant, a gallium zinc oxide in which zinc oxide is doped with gallium as a dopant, an indium zinc oxide in which zinc oxide is doped with indium as a dopant, or the like. Alternatively, it may also be possible to use IGZO, CuI, InSbO₄, ZnMgO, CuInO₂, MgIn₂O₄, CdO, ZnSnO₃, and the like.

For example, an electron transport layer or the like may be provided between the lower electrode 71R and the organic photoelectric conversion layer 72R, between the lower electrode 71G and the organic photoelectric conversion layer 72G, and between the lower electrode 71B and the organic photoelectric conversion layer 72B. The electron transport layer is provided to facilitate the supply of electrons generated in the organic photoelectric conversion layers 72R, 72G, and 72B to the lower electrodes 71R, 71G, and 71B, and is configured by, for example, titanium oxide, zinc oxide, or the like. Titanium oxide and zinc oxide may be stacked to configure the electron transport layer.

Each of the organic photoelectric conversion layers 72R, 72G, and 72B absorbs and photoelectrically converts light of a selective wavelength region, and transmits light of another wavelength region. Here, the light of a selective wavelength region is: for example, light of a wavelength region having a wavelength of 620 nm or more and less than 750 nm for the organic photoelectric conversion layer 72R; for example, light of a wavelength region having a wavelength of 480 nm or more and less than 620 nm for the organic photoelectric conversion layer 72G; and, for example, light of a wavelength region having a wavelength of 380 nm or more and less than 480 nm for the organic photoelectric conversion layer 72B.

The organic photoelectric conversion layers 72R, 72G, and 72B each have a configuration similar to that of the organic photoelectric conversion layer 12 in the foregoing embodiment. For example, the organic photoelectric conversion layers 72R, 72G, and 72B include three types of organic materials, for example. Similarly to the photoelectric conversion layer 12, the organic photoelectric conversion layers 72R, 72G, and 72B each include the above-described three types of organic materials of the first organic semiconductor material, the second organic semiconductor material, and the third organic semiconductor material.

For example, a hole transport layer or the like may be provided between the organic photoelectric conversion layer 72R and the upper electrode 73R, between the organic photoelectric conversion layer 72G and the upper electrode 73G, and between the organic photoelectric conversion layer 72B and the upper electrode 73B. The hole transport layer is provided to facilitate the supply of holes generated in the organic photoelectric conversion layers 72R, 72G, and 72B to the upper electrodes 73R, 73G, and 73B, and is configured by, for example, molybdenum oxide, nickel oxide, vanadium oxide, or the like. Alternatively, an organic material such as PEDOT (Poly(3,4-ethylenedioxythiophene)) and TPD (N,N′-Bis(3-methylphenyl)-N,N′-diphenylbenzidine) may be used to form the hole transport layer.

The upper electrode 73R is provided to extract holes generated in the organic photoelectric conversion layer 72R. The upper electrode 73G is provided to extract holes generated in the organic photoelectric conversion layer 72G. The upper electrode 73B is provided to extract holes generated in the organic photoelectric conversion layer 72G. Holes extracted from the upper electrodes 73R, 73G, and 73B are discharged, via respective transmission paths (unillustrated), to a p-type semiconductor region (unillustrated) inside the semiconductor substrate 30, for example. The upper electrodes 73R, 73G, and 73B are each configured by, for example, an electrically-conductive material such as gold (Au), silver (Ag), copper (Cu), and aluminum (Al). Similarly to the lower electrodes 71R, 71G, and 71B, the upper electrodes 73R, 73G, and 73B may each be configured by a transparent electrically-conductive material. In the photoelectric conversion element 1C, holes extracted from the upper electrodes 73R, 73G, and 73B are discharged. Thus, for example, when multiple photoelectric conversion elements 1C are disposed in the imaging device 100 described later, the upper electrodes 73R, 73G, and 73B may be provided in common to the unit pixels P.

An insulating layer 75 is provided to insulate the upper electrode 73R and the lower electrode 71G from each other, and the insulating layer 76 is provided to insulate the upper electrode 73G and the lower electrode 71B from each other. The insulating layers 75 and 76 are each configured by, for example, a metal oxide, a metal sulfide, or an organic matter. Examples of the metal oxide include silicon oxide (SiOₓ), aluminum oxide (AlOₓ), zirconium oxide (ZrOₓ), titanium oxide (TiOₓ), zinc oxide (ZnOₓ), tungsten oxide (WOₓ), magnesium oxide (MgOₓ), niobium oxide (NbOₓ), tin oxide (SnOₓ), and gallium oxide (GaOₓ). Examples of the metal sulfide include zinc sulfide (ZnS) and magnesium sulfide (MgS). For example, the band gap of a constituent material of each of the insulating layers 75 and 76 is preferably 3.0 eV or more.

As described above, the photoelectric conversion element 1C of the present embodiment has the configuration in which the red photoelectric conversion section 70R, the green photoelectric conversion section 70G, and the blue photoelectric conversion section 70B are stacked in this order. In such a configuration, it is possible to achieve effects similar to those of the foregoing first embodiment.

### 4. Fourth Embodiment

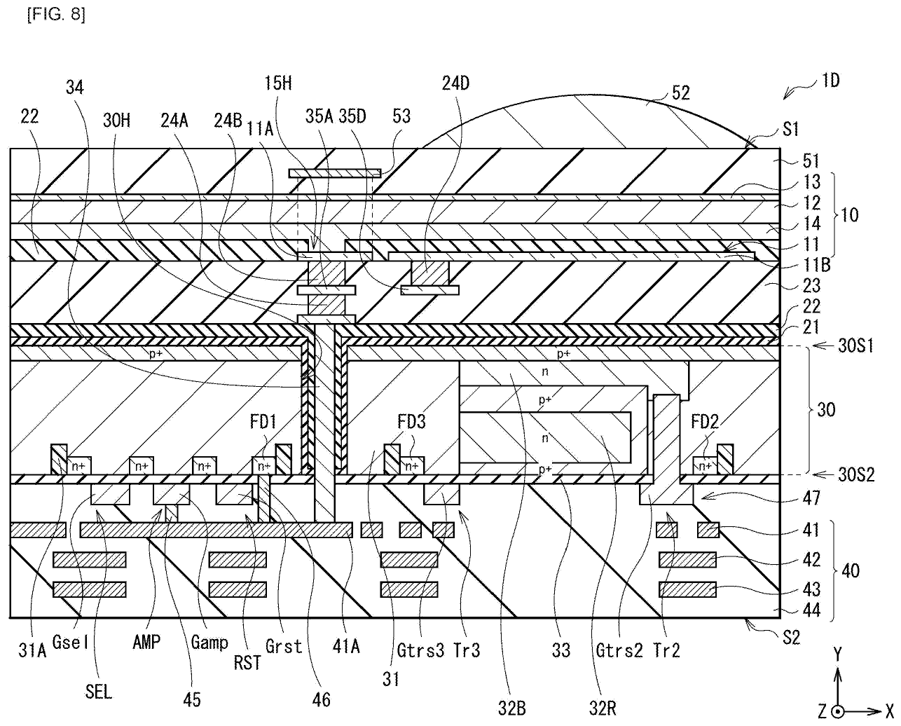

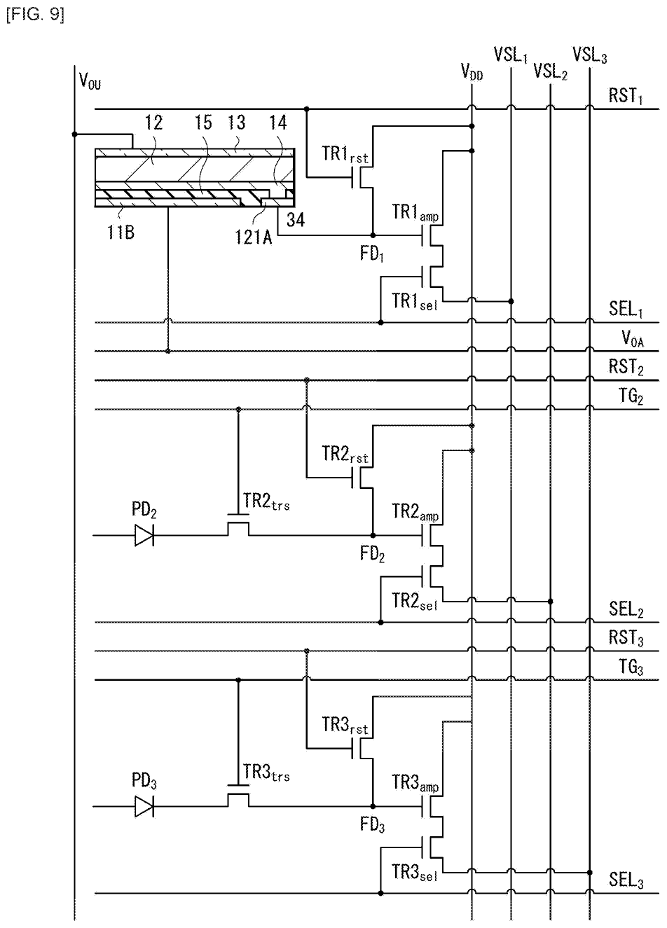

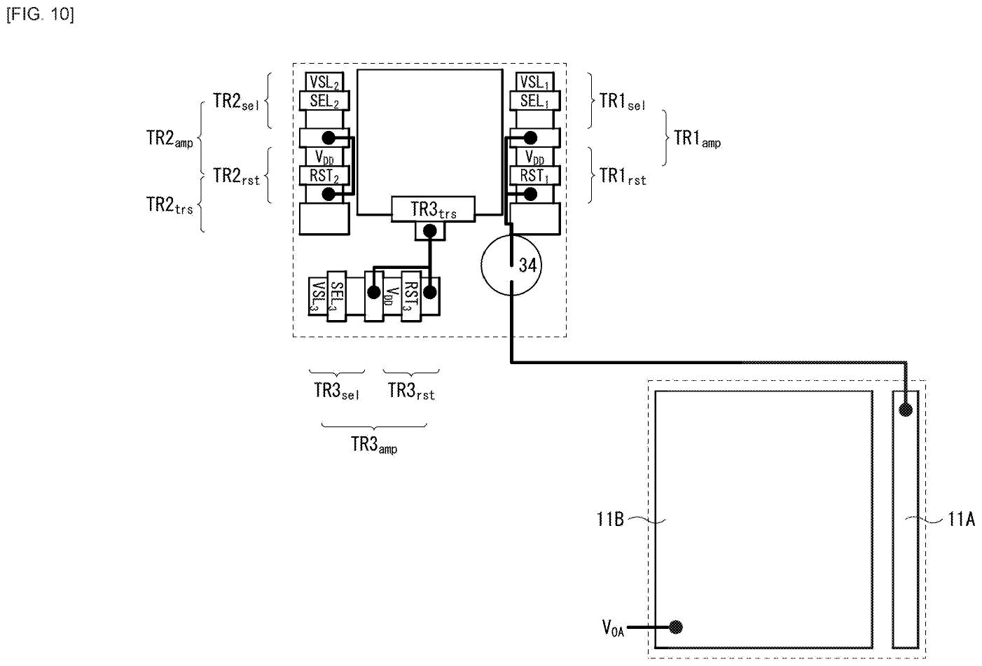

FIG. 8 illustrates an example of a cross-sectional configuration of a photoelectric conversion element (a photoelectric conversion element 1D) according to a fourth embodiment of the present disclosure. FIG. 9 is an equivalent circuit diagram of the photoelectric conversion element 1D illustrated in FIG. 8. FIG. 10 schematically illustrates arrangement of the lower electrode 11 and transistors constituting a control section of the photoelectric conversion element 1D illustrated in FIG. 8. The photoelectric conversion element 1D of the present embodiment differs from the foregoing first embodiment in that the lower electrode 11 includes multiple electrodes (e.g., a readout electrode 11A and an accumulation electrode 11B) independent of each other and that a semiconductor layer 14 is further provided between the lower electrode 11 and the photoelectric conversion layer 12.

It is to be noted that description is given, in the present embodiment, of a case of reading electrons, of the pairs of electrons and holes (electron-hole pairs) generated by photoelectric conversion, as signal charges (a case of setting an n-type semiconductor region as the photoelectric conversion layer).

Similarly to the foregoing first embodiment, the organic photoelectric conversion section 10 and the inorganic photoelectric conversion sections 32B and 32R selectively detect wavelengths (light) of wavelength bands different from each other and perform photoelectric conversion.

In the organic photoelectric conversion section 10, the lower electrode 11, the semiconductor layer 14, the photoelectric conversion layer 12, and the upper electrode 13 are stacked in this order from the side of the first surface 30A of the semiconductor substrate 30. In addition, an insulating layer 15 is provided between the lower electrode 11 and the semiconductor layer 14.

The lower electrode 11 is formed separately for each photoelectric conversion element 1D, for example, and is configured by the readout electrode 11A and the accumulation electrode 11B separated from each other with the insulating layer 15 interposed therebetween. The readout electrode 11A is electrically coupled to the semiconductor layer 14 via an opening 15H provided in the insulating layer 15. The readout electrode 11A is provided to transfer electric charge generated inside the photoelectric conversion layer 12 to the floating diffusion FD1, and is coupled to the floating diffusion FD 1 via the upper second contact 24B, the pad section 35A, the upper first contact 24A, the through-electrode 34, the coupling section 41A, and the lower second contact 46, for example. The accumulation electrode 11B is provided to accumulate, inside the semiconductor layer 14, electrons, of electric charges generated inside the photoelectric conversion layer 12, as signal charges. The accumulation electrode 11B is provided in a region opposed to and covering the light receiving surface of the inorganic photoelectric conversion sections 32B and 32R formed in the semiconductor substrate 30. The accumulation electrode 11B is preferably larger than the readout electrode 11A, which makes it possible to accumulate a number of electric charges. A voltage application circuit is coupled to the accumulation electrode 11B via a wiring line, and a voltage (e.g., V_{OA}) is independently applied thereto.

FIG. 1 illustrates an example in which the semiconductor layer 14, the photoelectric conversion layer 12, and the upper electrode 13 are provided as successive layers common to multiple photoelectric conversion elements 1D; however, the semiconductor layer 14, the photoelectric conversion layer 12, and the upper electrode 13 may be formed separately for each photoelectric conversion element 1D, for example.

The semiconductor layer 14 is provided under the photoelectric conversion layer 12, specifically, between the insulating layer 15 and the photoelectric conversion layer 12, and is provided to accumulate signal charges generated in the photoelectric conversion layer 12. It is preferable for the semiconductor layer 14 to have electric charge mobility higher than and to be formed by using a material having a band gap larger than those of the photoelectric conversion layer 12. For example, the band gap of a constituent material of the semiconductor layer 14 is preferably 3.0 eV or more. Examples of such a material include an oxide semiconductor material such as IGZO and an organic semiconductor material. Examples of the organic semiconductor material include transition metal dichalcogenide, silicon carbide, diamond, graphene, a carbon nanotube, a condensed polycyclic hydrocarbon compound, and a condensed heterocyclic compound. Providing the semiconductor layer 14 configured by the above-mentioned material under the photoelectric conversion layer 12 makes it possible to prevent recombination of electric charges at the time of accumulation of electric charges and thus to improve transfer efficiency.

It is to be noted that, as in a photoelectric conversion element 1E described later, for example, the semiconductor layer 14 may have, for example, a stacked structure of a layer (a layer 14A) and a layer (a layer 14B). The layer 14A is provided to prevent electric charges accumulated in the semiconductor layer 14 from being trapped at an interface with the insulating layer 15 and transfer the electric charges efficiently to the readout electrode 11A. The layer 14B is provided to prevent oxygen desorption on a front surface of the layer 14A and prevent electric charges generated in the photoelectric conversion layer 12 from being trapped at an interface with the semiconductor layer 14.

The insulating layer 15 is provided to electrically separate the accumulation electrode 11B and the semiconductor layer 14 from each other. The insulating layer 15 is provided on the interlayer insulating layer 23, for example, to cover the lower electrode 11. The insulating layer 15 is provided with an opening 15H on the readout electrode 11A, and the readout electrode 11A and the semiconductor layer 14 are electrically coupled together via the opening 15H. The insulating layer 15 is configured by, for example, a monolayer film of one of silicon oxide (SiOₓ), silicon nitride (SiNₓ), silicon oxynitride (SiON), or the like, or a stacked film of two or more thereof.

The second surface 30B of the semiconductor substrate 30 is provided with a readout circuit constituting a control section in each of the organic photoelectric conversion section 10 and the inorganic photoelectric conversion sections 32B and 32R. Specifically, there are provided: a reset transistor TR1rst, an amplifier transistor TR1amp, and a selection transistor TR1sel constituting a readout circuit of the organic photoelectric conversion section 10; a transfer transistor TR2trs (TR2), a reset transistor TR2rst, an amplifier transistor TR2amp, and a selection transistor TR2sel constituting a readout circuit of the inorganic photoelectric conversion section 32B; and a transfer transistor TR3trs (TR3), a reset transistor TR3rst, an amplifier transistor TR3amp, and a selection transistor TR3sel constituting a readout circuit of the inorganic photoelectric conversion section 32R.

The protective layer 51 is provided above the upper electrode 13. In the protective layer 51, for example, a light blocking film 53 is provided at a position corresponding to the readout electrode 11A. This light blocking film 53 may be provided to cover at least a region of the readout electrode 11A in direct contact with the semiconductor layer 14, without being engaged with at least the accumulation electrode 11B.

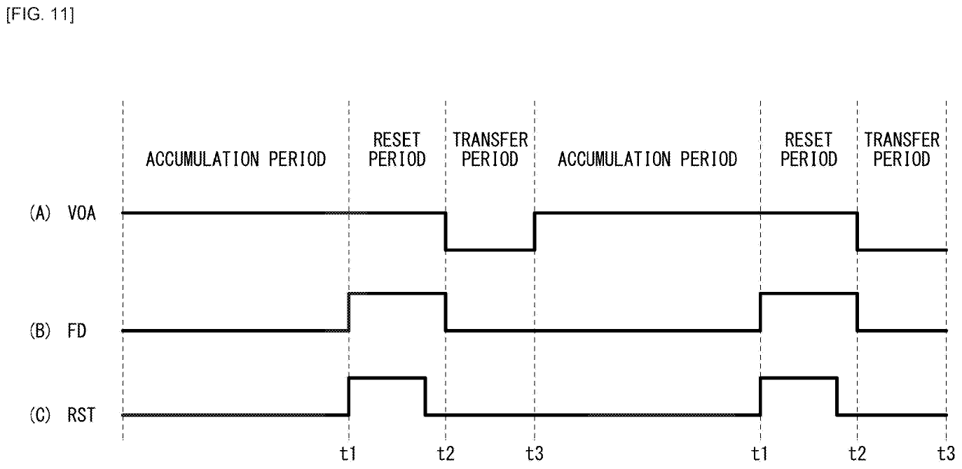

FIG. 11 illustrates an operational example of the photoelectric conversion element 1D. (A) indicates a potential in the accumulation electrode 11B, (B) indicates a potential in the floating diffusion FD1 (readout electrode 11A), and (C) indicates a potential in the gate (Gsel) of the reset transistor TR1rst. In the photoelectric conversion element 1D, voltages are individually applied to the readout electrode 11A and the accumulation electrode 11B.

In the photoelectric conversion element 1D, during an accumulation period, a potential V1 is applied from the drive circuit to the readout electrode 11A, and a potential V2 is applied to the accumulation electrode 11B. Here, as for the potentials V1 and V2, V2>V1 holds true. This allows electric charges (signal charges; electrons) generated by photoelectric conversion to be attracted to the accumulation electrode 11B and accumulated in a region, of the semiconductor layer 14, opposed to the accumulation electrode 11B (accumulation period). Incidentally, a potential in the region, of the semiconductor layer 14, opposed to the accumulation electrode 11B has a value on a more negative side as time of photoelectric conversion elapses. It is to be noted that holes are sent from the upper electrode 13 to the drive circuit.

In the photoelectric conversion element 1D, a reset operation is performed at a later stage in the accumulation period. Specifically, at timing t1, a scanning section changes a voltage of a reset signal RST from a low level to a high level. This brings, in the unit pixel P, the reset transistor TR1rst into an ON state; as a result, a voltage of the floating diffusion FD1 is set to a power source voltage, and the voltage of the floating diffusion FD1 is reset (reset period).

After completion of the reset operation, electric charges are read. Specifically, at timing t2, a potential V3 is applied to the readout electrode 11A from the drive circuit, and a potential V4 is applied to the accumulation electrode 11B. Here, as for the potentials V3 and V4, V3<V4 holds true. This allows electric charges accumulated in a region corresponding to the accumulation electrode 11B to be read from the readout electrode 11A to the floating diffusion FD1. That is, the electric charges accumulated in the semiconductor layer 14 are read by the control section (transfer period).

After completion of the reading operation, the potential V1 is applied again to the readout electrode 11A from the drive circuit, and the potential V2 is applied to the accumulation electrode 11B. This allows electric charges generated by photoelectric conversion to be attracted to the accumulation electrode 11B and accumulated in a region, of the photoelectric conversion layer 12, opposed to the accumulation electrode 11B (accumulation period).

As described above, the present technology is applicable to the photoelectric conversion element (photoelectric conversion element 1D) in which the lower electrode 11 includes the multiple electrodes (readout electrode 11A and accumulation electrode 11B).

### 5. Fifth Embodiment

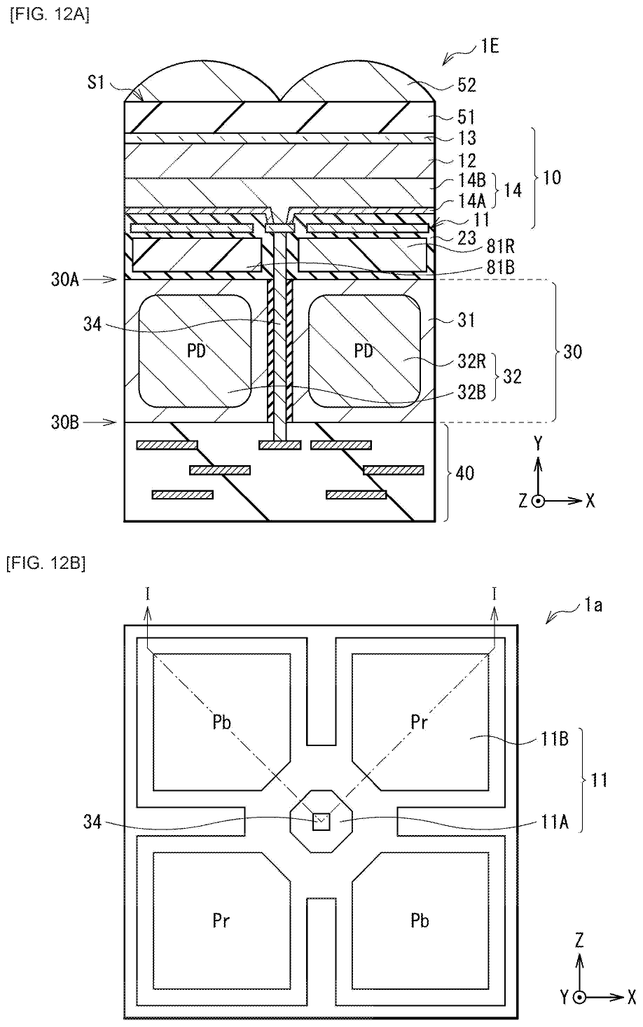

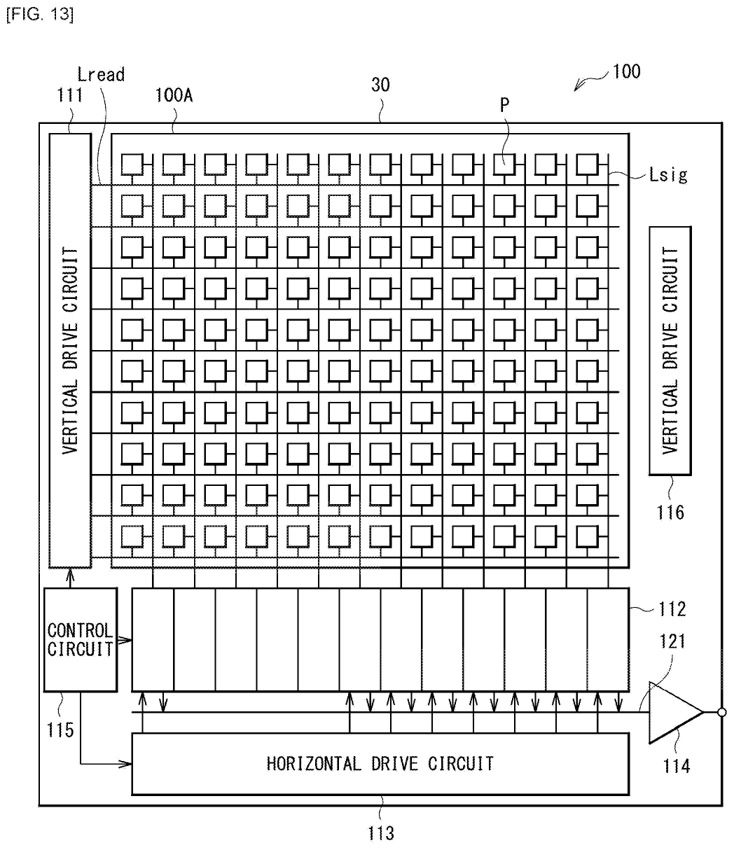

FIG. 12A schematically illustrates an example of a cross-sectional configuration of a photoelectric conversion element (a photoelectric conversion element 1E) according to a fifth embodiment of the present disclosure. FIG. 12B schematically illustrates an example of a planar configuration of the photoelectric conversion element 1E illustrated in FIG. 12A. FIG. 12A illustrates a cross-section along a line I-I illustrated in FIG. 12B. The photoelectric conversion element 1E is, for example, a stacked imaging element in which an inorganic photoelectric conversion section 32 and the organic photoelectric conversion section 10 are stacked. In the pixel section 100A of the imaging device (e.g., imaging device 100) described later, a pixel unit 1a including four pixels arranged in two rows×two columns is a repeating unit, for example, as illustrated in FIG. 12B, and the pixel units 1a are repeatedly arranged in array in a row direction and a column direction.

The organic photoelectric conversion section 10 includes, for example, the lower electrode 11, the insulating layer 15, the semiconductor layer 14, the photoelectric conversion layer 12, and the upper electrode 13. The lower electrode 11, the insulating layer 15, the semiconductor layer 14, the photoelectric conversion layer 12, and the upper electrode 13 each have a configuration similar to that of the organic photoelectric conversion section 10 in the foregoing fourth embodiment. The inorganic photoelectric conversion section 32 detects light of a wavelength region different from that of the organic photoelectric conversion section 10.

The photoelectric conversion element 1E of the present embodiment has a configuration in which color filters (color filters 81R) each of which selectively transmits at least red light (R) and color filters (color filters 81B) each of which selectively transmits at least blue light (B) are arranged on the respective diagonal lines between the inorganic photoelectric conversion section 32 and the organic photoelectric conversion section 10. The organic photoelectric conversion section 10 (photoelectric conversion layer 12) is configured to selectively absorb a wavelength corresponding to green light, for example. This allows the organic photoelectric conversion section 10 and the respective inorganic photoelectric conversion sections 32 (inorganic photoelectric conversion sections 32R and 32G) arranged below the color filters 81R and 81B to acquire signals corresponding to blue light (B) or red light (R). The photoelectric conversion element 1E according to the present embodiment allows the respective photoelectric conversion sections of R, G, and B to each have a larger area than that of a photoelectric conversion element having a typical Bayer arrangement. This makes it possible to improve the S/N ratio.

### 6. Application Examples

### Application Example 1

FIG. 13 illustrates an example of an overall configuration of the imaging device (imaging device 100) including the photoelectric conversion element (e.g., photoelectric conversion element 1A) illustrated in FIG. 1, for example.

The imaging device 100 is, for example, a CMOS image sensor. The imaging device 100 takes in incident light (image light) from a subject via an optical lens system (unillustrated), and converts the amount of incident light formed as an image on an imaging surface into electric signals in units of pixels to output the electric signals as pixel signals. The imaging device 100 includes the pixel section 100A as an imaging area on the semiconductor substrate 30. In addition, the imaging device 100 includes, for example, a vertical drive circuit 111, a column signal processing circuit 112, a horizontal drive circuit 113, an output circuit 114, a control circuit 115, and an input/output terminal 116 in a peripheral region of this pixel section 100A.

The pixel section 100A includes, for example, the multiple unit pixels P that are two-dimensionally arranged in matrix. The unit pixels P are provided, for example, with a pixel drive line Lread (specifically, a row selection line and a reset control line) for each of pixel rows and provided with the vertical signal line Lsig for each of pixel columns. The pixel drive line Lread transmits drive signals for reading signals from the pixels. One end of the pixel drive line Lread is coupled to an output end of the vertical drive circuit 111 corresponding to each of the rows.

The vertical drive circuit 111 is a pixel drive section that is configured by a shift register, an address decoder, and the like and drives the unit pixels P of the pixel section 100A on a row-by-row basis, for example. Signals outputted from the respective unit pixels P in the pixel rows selectively scanned by the vertical drive circuit 111 are supplied to the column signal processing circuit 112 through the respective vertical signal lines Lsig. The column signal processing circuit 112 is configured by an amplifier, a horizontal selection switch, and the like provided for each of the vertical signal lines Lsig.

The horizontal drive circuit 113 is configured by a shift register, an address decoder, and the like. The horizontal drive circuit 113 drives horizontal selection switches of the column signal processing circuit 112 in order while scanning the horizontal selection switches. The selective scanning by the horizontal drive circuit 113 causes signals of the respective pixels transmitted through the respective vertical signal lines Lsig to be outputted to a horizontal signal line 121 in order and causes the signals to be transmitted to the outside of the semiconductor substrate 30 through the horizontal signal line 121.

The output circuit 114 performs signal processing on signals sequentially supplied from the respective column signal processing circuits 112 via the horizontal signal line 121, and outputs the signals. The output circuit 114 performs, for example, only buffering in some cases, and performs black level adjustment, column variation correction, various kinds of digital signal processing, and the like in other cases.

The circuit portion including the vertical drive circuit 111, the column signal processing circuit 112, the horizontal drive circuit 113, the horizontal signal line 121, and the output circuit 114 may be formed directly on the semiconductor substrate 30, or may be provided on an external control IC. In addition, the circuit portion may be formed in another substrate coupled by a cable or the like.

The control circuit 115 receives a clock supplied from the outside of the semiconductor substrate 30, data for an instruction about an operation mode, and the like and also outputs data such as internal information on the imaging device 100. The control circuit 115 further includes a timing generator that generates a variety of timing signals, and controls driving of the peripheral circuits including the vertical drive circuit 111, the column signal processing circuit 112, the horizontal drive circuit 113, and the like on the basis of the variety of timing signals generated by the timing generator.

The input/output terminal 116 exchanges signals with the outside.

### Application Example 2

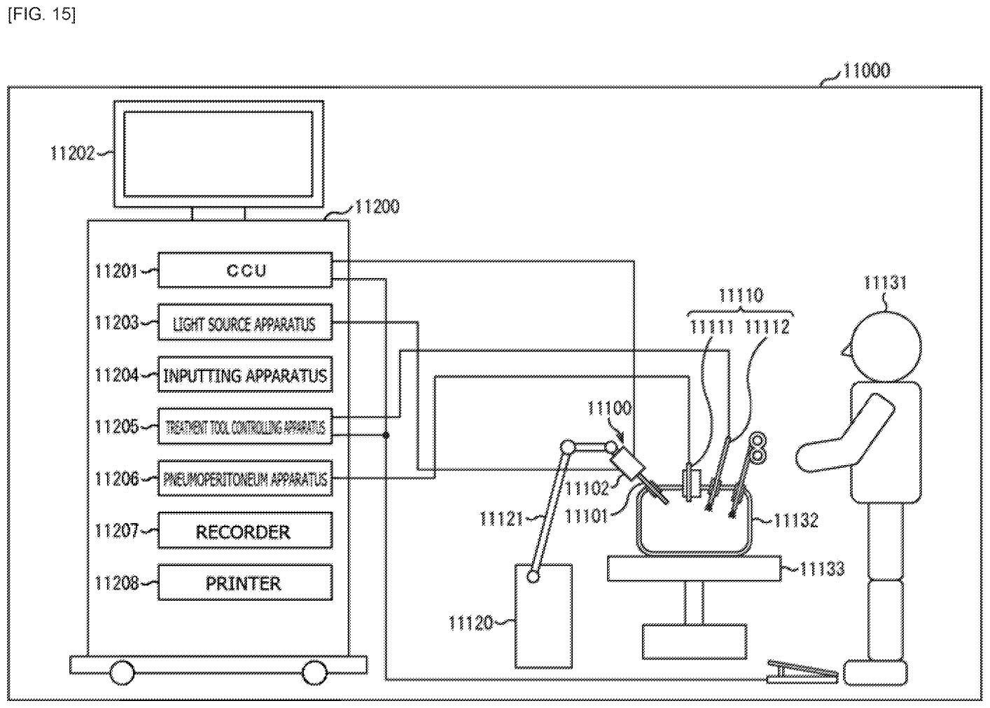

The above-described imaging device 100 is applicable, for example, to any type of electronic apparatus with an imaging function including a camera system such as a digital still camera and a video camera, a mobile phone having an imaging function, and the like. FIG. 14 illustrates an outline configuration of an electronic apparatus 1000.

The electronic apparatus 1000 includes, for example, an optical system 1001, a shutter device 1002, the imaging device 100, a DSP (Digital Signal Processor) circuit 1003, a frame memory 1004, a display unit 1005, a recording unit 1006, an operation unit 1007, and a power source unit 1008. They are coupled to each other via a bus line 1009.

The optical system 1001 includes one or multiple lenses, and guides light (incident light) from a subject to the imaging device 100 to form an image on a light-receiving surface of the imaging device 100. The shutter device 1002 is disposed between the optical system 1001 and the imaging device 100, and controls periods of light irradiation and light blocking with respect to the imaging device 100 under the control of the drive circuit.

The DSP circuit 1003 is a signal processing circuit that processes signals supplied from the imaging device 100. The DSP circuit 1003 outputs image data obtained by processing the signals from the imaging device 100. The frame memory 1004 temporarily holds the image data processed by the DSP circuit 1003 in units of frames.

The display unit 1005 includes, for example, a panel-type display device such as a liquid crystal panel or an organic EL (Electro Luminescence) panel, and records image data of a moving image or a still image captured by the imaging device 100 in a recording medium such as a semiconductor memory or a hard disk.

The operation unit 1007 outputs an operation signal for a variety of functions of the electronic apparatus 1000 in accordance with an operation by a user. The power source unit 1008 appropriately supplies the DSP circuit 1003, the frame memory 1004, the display unit 1005, the recording unit 1006, and the operation unit 1007 with various kinds of power for operations of these supply targets.

### 7. Practical Application Examples

### Example of Practical Application to Endoscopic Surgery System

The technology according to an embodiment of the present disclosure (present technology) is applicable to various products. For example, the technology according to an embodiment of the present disclosure may be applied to an endoscopic surgery system.

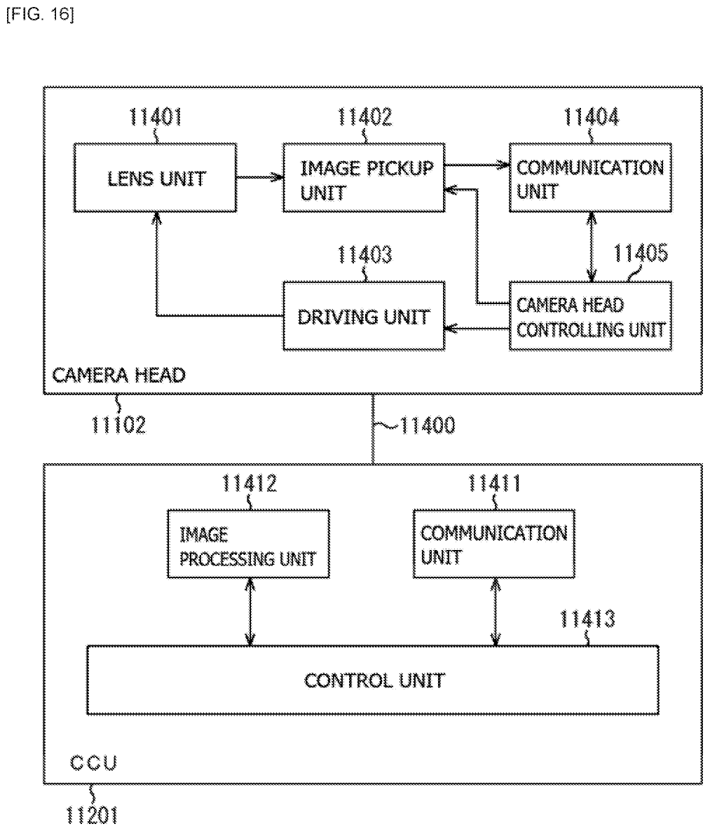

FIG. 15 is a view depicting an example of a schematic configuration of an endoscopic surgery system to which the technology according to an embodiment of the present disclosure (present technology) can be applied.

In FIG. 15, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

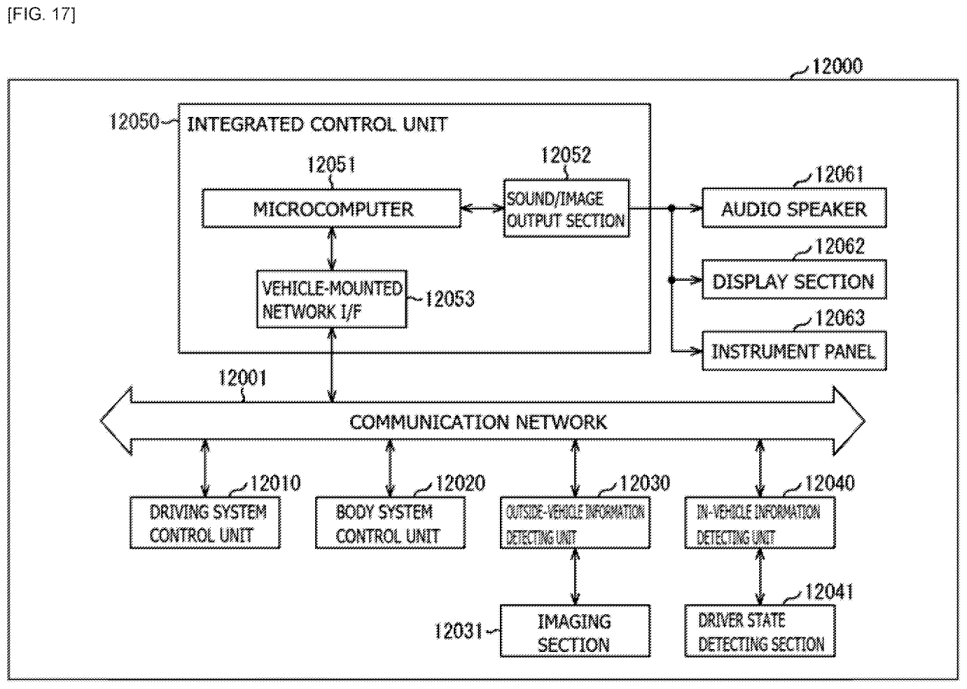

FIG. 16 is a block diagram depicting an example of a functional configuration of the camera head 11102 and the CCU 11201 depicted in FIG. 15.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is applicable to, for example, the image pickup unit 11402 of the configurations described above. Applying the technology according to an embodiment of the present disclosure to the image pickup unit 11402 makes it possible to improve detection accuracy.

It is to be noted that although the endoscopic surgery system has been described as an example here, the technology according to an embodiment of the present disclosure may also be applied to, for example, a microscopic surgery system, and the like.

### (Example of Practical Application to Mobile Body)

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, a robot, a construction machine, and an agricultural machine (tractor).

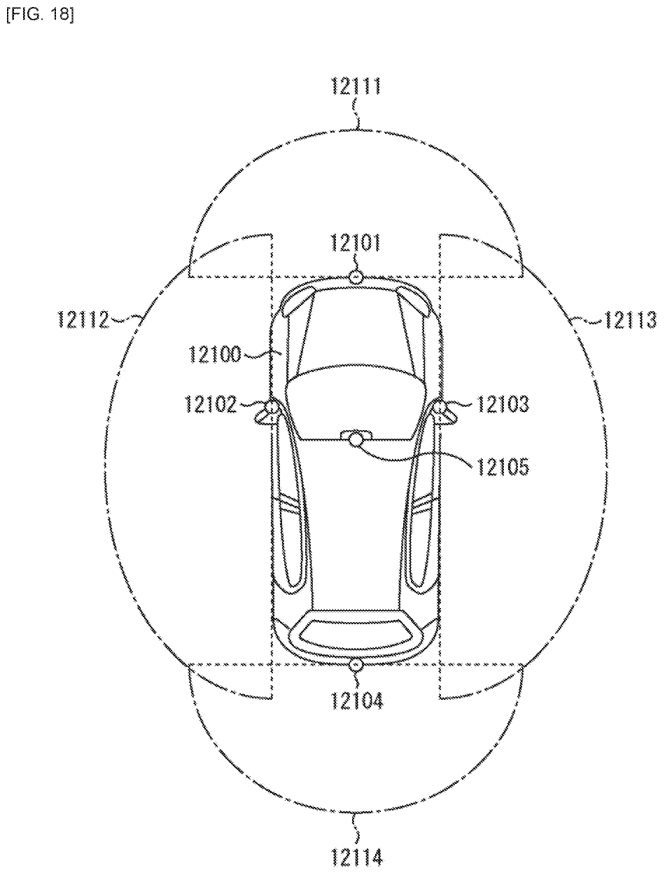

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

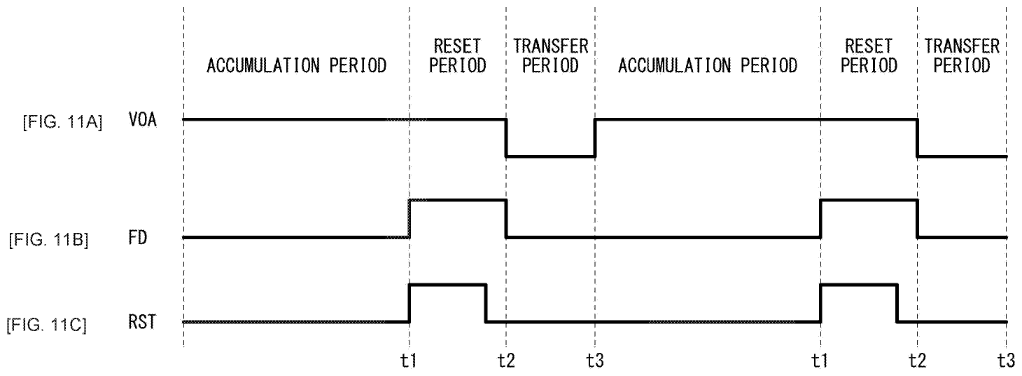

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

### 8. Example

Next, description is given of Example of the present disclosure. In the present Example, each monolayer film of the first organic semiconductor material, the second organic semiconductor material, and the third organic semiconductor material described above, a mixed film in which the first organic semiconductor material, the second organic semiconductor material, and the third organic semiconductor material are mixed, and photoelectric conversion elements (device samples) using the films as photoelectric conversion layers were prepared to evaluate each characteristics.

### Experiment 1

### (Preparation of Single Film Sample)

In Experimental Example 1, a monolayer film including C₆₀ fullerene (first organic semiconductor material, formula (1-1)) was formed using the following method. First, a quartz substrate was washed by UV/ozone treatment, then the quartz substrate was transferred to a vacuum deposition machine, and C₆₀ fullerene (formula (1-1)) was deposited on the quartz substrate while rotating a substrate holder in a state of being depressurized to 1×10⁻⁵ Pa or less.

In addition thereto, preparations were performed in Experimental Examples 2 to 18 using a method similar to that of Experimental Example 1. In Experimental Examples 2 to 9, second organic semiconductor materials represented by Formulae (2-1) to (2-8) were used. In Experimental Examples 10 to 13, third organic semiconductor materials represented by Formulae (3-1) to (3-4) were used. In Experimental Examples 14 to 16, second organic semiconductor materials represented by Formulae (4-1) to (4-3) were used. In Experimental Examples 17 and 18, third organic semiconductor materials represented by Formulae (5-1) and (5-2) were used. Table 1 summarizes organic materials used in respective Experimental Examples 1 to 18.

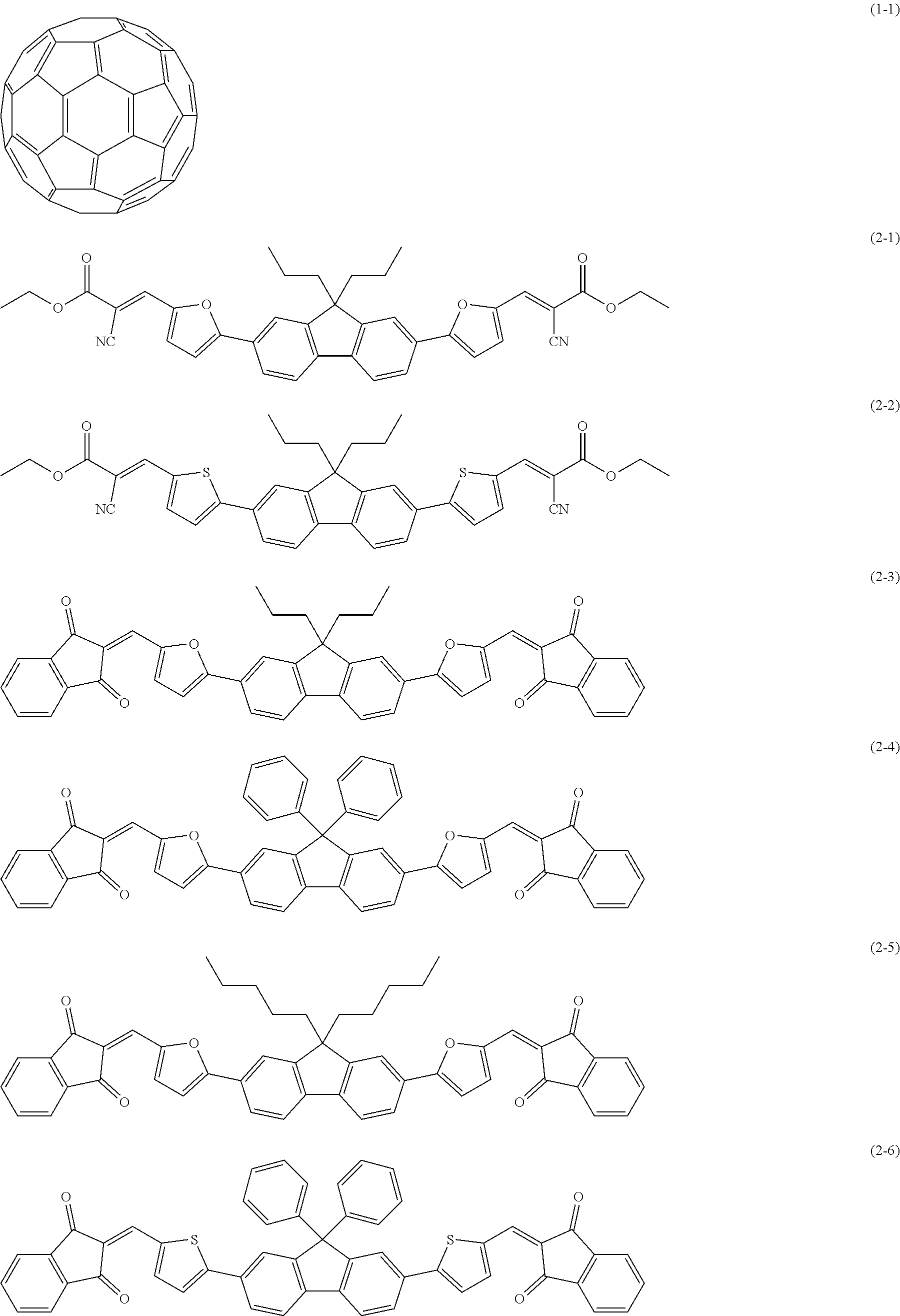

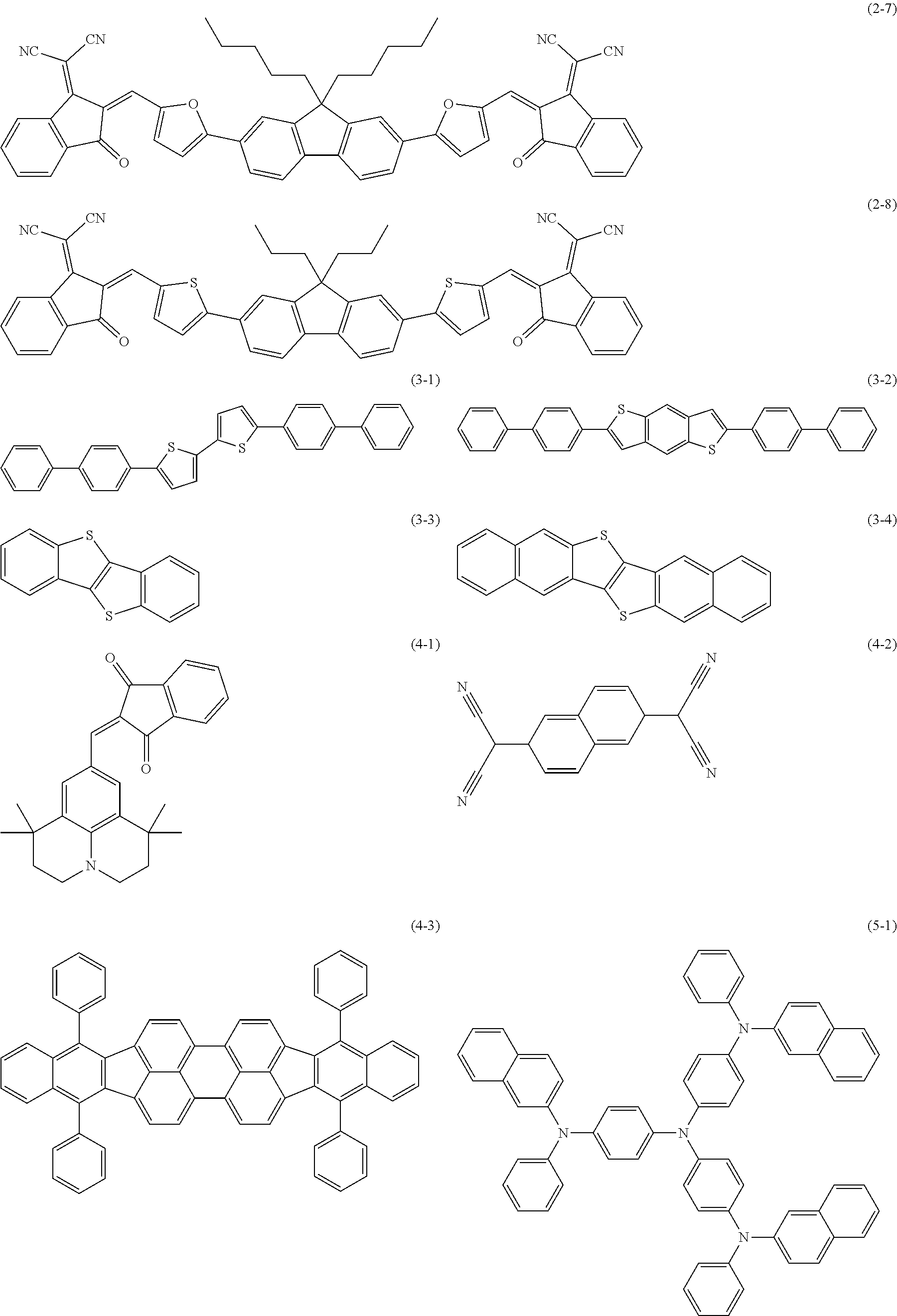

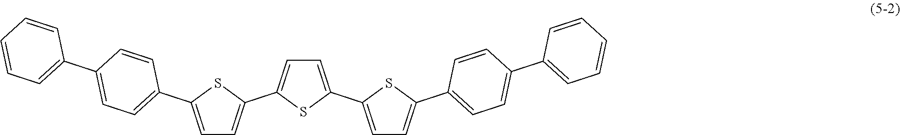 [SMILES: c1ccc(-c2ccc(-c3ccc(-c4ccc(-c5ccc(-c6ccc(-c7ccccc7)cc6)s5)s4)s3)cc2)cc1]

TABLE 1

| | First Organic | Second Organic | Third Organic |
|---|---|---|---|
| | Semiconductor | Semiconductor | Semiconductor |
| | Material | Material | Material |
| Experimental | Formula (1-1) | | |
| Example 1 | | | |
| Experimental | | Formula (2-1) | |
| Example 2 | | | |
| Experimental | | Formula (2-2) | |
| Example 3 | | | |
| Experimental | | Formula (2-3) | |
| Example 4 | | | |
| Experimental | | Formula (2-4) | |
| Example 5 | | | |
| Experimental | | Formula (2-5) | |
| Example 6 | | | |
| Experimental | | Formula (2-6) | |
| Example 7 | | | |
| Experimental | | Formula (2-7) | |
| Example 8 | | | |
| Experimental | | Formula (2-8) | |
| Example 9 | | | |
| Experimental | | | Formula (3-1) |
| Example 10 | | | |
| Experimental | | | Formula (3-2) |
| Example 11 | | | |
| Experimental | | | Formula (3-3) |
| Example 12 | | | |
| Experimental | | | Formula (3-4) |
| Example 13 | | | |
| Experimental | | Formula (4-1) | |
| Example 14 | | | |
| Experimental | | Formula (4-2) | |
| Example 15 | | | |
| Experimental | | Formula (4-3) | |
| Example 16 | | | |
| Experimental | | | Formula (5-1) |
| Example 17 | | | |
| Experimental | | | Formula (5-2) |
| Example 18 | | | |

The single film samples prepared as Experimental Examples 1 to 18 were used to evaluate the HOMO level, the LUMO level, and the energy gap ΔE₁₂. An ultraviolet photoelectron spectroscopy (UPS) was used to acquire a kinetic energy distribution of electrons emitted from a sample surface upon irradiation with an ultraviolet ray, and an energy width of a spectrum thereof was subtracted from an energy value of the irradiated ultraviolet ray to obtain the HOMO level. The LUMO level was calculated as a value obtained by adding, to the HOMO level, an energy value of an optical absorption edge obtained by spectral characteristic evaluation. The energy gap ΔE₁₂ was calculated using the following Numerical Expression (1).

ΔE₁₂=|(HOMO level of second organic semiconductor material)−(LUMO level of first organic semiconductor material)| (1)

Furthermore, spectral characteristics of the single film samples prepared as Experimental Examples 1 to 18 were evaluated. As for the spectral characteristics, absorption spectroscopy and reflection spectroscopy were measured using a spectrophotometer, absorptivity of each of the samples was calculated using the following Numerical Expression (2), and an absorption coefficient α was further calculated using Numerical Expression (3). Table 2 summarizes results of Experimental Examples 10 to 13 and Experimental Examples 17 and 18 as portion of the outcome.

Absorptivity A=100%−T%/(100%−R%)×100 (2)

(T %: transmittance, R %: reflectance)

Absorption coefficient α=−Ln[(100−A/100)]/d (3)

(A: absorptivity, d: film thickness)

TABLE 2

| | | Optical Absorption Edge of Third |
|---|---|---|
| | | Organic Semiconductor Material |
| | Third Organic | Optical Absorption Edge Wavelength |
| | Semiconductor | (nm) with Linear Absorption |
| | Material | Coefficient of 10000 or less |
| Experimental | Formula (3-1) | 471 |
| Example 10 | | |
| Experimental | Formula (3-2) | 450 |
| Example 11 | | |
| Experimental | Formula (3-3) | 335 |
| Example 12 | | |
| Experimental | Formula (3-4) | 478 |
| Example 13 | | |
| Experimental | Formula (5-1) | 423 |
| Example 17 | | |
| Experimental | Formula (5-2) | 587 |
| Example 18 | | |

### Experiment 2

### (Preparation of Mixed Film Sample)

In Experimental Example 19, a mixed film including C₆₀ fullerene (first organic semiconductor material) represented by Formula (1-1), the compound (second organic semiconductor material) represented by Formula (2-1), and the compound (third organic semiconductor material) represented by Formula (3-1) was formed using the following method. First, a quartz substrate was washed by UV/ozone treatment, then the quartz substrate was transferred to a vacuum deposition machine, and an electron blocking layer having a film thickness of 10 nm was formed on the quartz substrate while rotating a substrate holder in a state of being depressurized to 1×10⁻⁵ Pa or less, using PC-IC represented by the following formula (6). Subsequently, at a substrate temperature of 40° C., C₆₀ fullerene represented by the formula (1-1), a DπA compound represented by the formula (2-3), and BP-rBDT represented by the above formula (3-3) were formed as films at film formation rates of 0.25 Å/sec, 0.50 Å/sec, and 0.50 Å/sec, respectively, and at a thickness of 230 nm. Next, at a substrate temperature of 0° C., NDI-35 represented by the following formula (7) was used to form, as a film, a hole blocking layer having a film thickness of 10 nm, which was adopted as a mixed film sample for evaluation of a crystalline property.

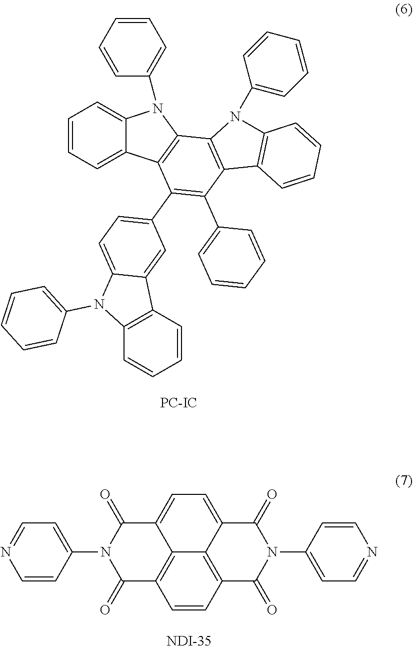

In addition thereto, preparations were performed in Experimental Examples 20 to 43 using a method similar to that in Experimental Example 19. Table 3 summarizes organic materials used in respective Experimental Examples 20 to 43.

TABLE 3

| | First Organic | Second Organic | Third Organic |
|---|---|---|---|
| | Semiconductor | Semiconductor | Semiconductor |
| | Material | Material | Material |
| Experimental | Formula (1-1) | Formula (2-1) | Formula (3-1) |
| Example 19 | | | |
| Experimental | Formula (1-1) | Formula (2-1) | Formula (3-2) |
| Example 20 | | | |
| Experimental | Formula (1-1) | Formula (2-1) | Formula (3-3) |
| Example 21 | | | |
| Experimental | Formula (1-1) | Formula (2-1) | Formula (3-4) |
| Example 22 | | | |
| Experimental | Formula (1-1) | Formula (2-2) | Formula (3-2) |
| Example 23 | | | |
| Experimental | Formula (1-1) | Formula (2-2) | Formula (3-4) |
| Example 24 | | | |
| Experimental | Formula (1-1) | Formula (2-3) | Formula (3-2) |
| Example 25 | | | |
| Experimental | Formula (1-1) | Formula (2-3) | Formula (3-3) |
| Example 26 | | | |
| Experimental | Formula (1-1) | Formula (2-4) | Formula (3-2) |
| Example 27 | | | |
| Experimental | Formula (1-1) | Formula (2-4) | Formula (3-3) |
| Example 28 | | | |
| Experimental | Formula (1-1) | Formula (2-5) | Formula (3-2) |
| Example 29 | | | |
| Experimental | Formula (1-1) | Formula (2-5) | Formula (3-3) |
| Example 30 | | | |
| Experimental | Formula (1-1) | Formula (2-6) | Formula (3-2) |
| Example 31 | | | |
| Experimental | Formula (1-1) | Formula (2-6) | Formula (3-3) |
| Example 32 | | | |
| Experimental | Formula (1-1) | Formula (2-7) | Formula (3-2) |
| Example 33 | | | |
| Experimental | Formula (1-1) | Formula (2-7) | Formula (3-3) |
| Example 34 | | | |
| Experimental | Formula (1-1) | Formula (2-8) | Formula (3-2) |
| Example 35 | | | |
| Experimental | Formula (1-1) | Formula (2-8) | Formula (3-3) |
| Example 36 | | | |
| Experimental | Formula (1-1) | Formula (4-1) | Formula (3-2) |
| Example 37 | | | |
| Experimental | Formula (1-1) | Formula (4-1) | Formula (3-3) |
| Example 38 | | | |
| Experimental | Formula (1-1) | Formula (4-2) | Formula (3-2) |
| Example 39 | | | |
| Experimental | Formula (1-1) | Formula (4-3) | Formula (3-2) |
| Example 40 | | | |
| Experimental | Formula (1-1) | Formula (2-3) | Formula (5-1) |
| Example 41 | | | |
| Experimental | Formula (1-1) | Formula (2-3) | Formula (5-2) |
| Example 42 | | | |
| Experimental | Formula (1-1) | Formula (2-4) | Formula (5-2) |
| Example 43 | | | |

The mixed film samples prepared as Experimental Examples 19 to 43 were evaluated by X-ray diffractometry in terms of a diffraction peak position and a crystalline property. The diffraction peak position and the crystalline property were evaluated by irradiating each sample with an X-ray using an X-ray diffractometer with CuKα employed as an X-ray generation source and by performing X-ray diffractometry measurement in an out-of-plane direction at a range of 2θ=2° to 35° using an oblique incidence method. As for X-ray diffraction spectrum, peaks of regions of 18° to 21°, 22° to 24°, and 26° to 30° of Bragg angle (2θ) were set as the first, second, and third peaks in order. The first, second, and third peak positions were determined by fitting the respective peaks from background-subtracted X-ray diffraction spectrum using a Pearson VII function. The crystalline property was judged from presence or absence of the first, second, and third peaks.

Further, as for Experimental Examples 19 to 43, absorption spectroscopy and reflection spectroscopy were measured using a spectrophotometer, absorptivity of each of the samples was calculated using the above Numerical Expression (2), and an absorption coefficient α was further calculated using the above Numerical Expression (3). In addition, heat resistance and wavelength selectivity based on absorptivity A of Experimental Examples 19 to 43 were evaluated. It is to be noted that respective evaluation results are summarized in Table 4 together with results of Experiment 3 described later.

As for the heat resistance, in Experimental Examples 19 to 43, an annealing treatment was performed at 150° C. for 210 minutes under a nitrogen (N₂) atmosphere, followed by cooling to a room temperature. Thereafter, the absorption coefficient α was evaluated, and relative values of the absorption coefficient α after heating with respect to the absorption coefficient α before the heating at respective wavelengths were determined to evaluate the heat resistance as an average value of the relative values. It is assumed that, as the relative value becomes smaller, the heat resistance becomes higher.

As for the wavelength selectivity, first, the absorptivity A of each sample of Experimental Examples 19 to 43 was divided into respective wavelength bands of R/G/B as described below, and integral values of the absorptivity thereof were calculated.
Blue region A_{B}: 380 nm to 500 nm
Green region A_{G}: 480 nm to 620 nm
Red region A_{R}: 620 nm to 750 nm

The wavelength selectivity was evaluated using the following standard. In Experimental Examples 44 to 49 targeting blue light, A denotes a case where an integral value of absorptivity of the blue wavelength band satisfies the following Numerical Expression (4), and B denotes a case where the integral value does not satisfy the following Numerical Expression (4). In Experimental Examples 50 to 57 and Experimental Examples 62 to 68 targeting green light, A denotes a case where an integral value of absorptivity of the green wavelength band satisfies the following Numerical Expression (5), and B denotes a case where the integral value does not satisfy the following Numerical Expression (5). In Experimental Examples 58 to 61 targeting red light, A denotes a case where an integral value of absorptivity of the red wavelength band satisfies the following Numerical Expression (6), and B denotes a case where the integral value does not satisfy the following Numerical Expression (6).

100≤(A_{B}+A_{G})/A_{B}<130 (4)

100≤(A_{B}+A_{G})/A_{G}<150, and 100≤(A_{G}+A_{R})/A_{G}<130) (5)

100≤(A_{G}+A_{R})/A_{R}<150 (6)

### Experiment 3

### (Preparation of Device Sample)

First, an ITO film having a thickness of 100 nm was formed on a quartz substrate using a sputtering device, and then the ITO film was patterned by photolithography and etching to form an ITO electrode (lower electrode). The quartz substrate was washed with UV/ozone treatment. Subsequently, the quartz substrate was transferred to a vacuum deposition machine, and an electron blocking layer, a photoelectric conversion layer, and a hole blocking layer having configurations similar to those of the above-described mixed film sample (Experimental Example 19) were formed as films in this order while rotating a substrate holder in a state of being depressurized to 1×10⁻⁵ Pa or less. Subsequently, an ITO electrode (upper electrode) having a film thickness of 50 nm was formed on the hole blocking layer. As described above, a device sample having a photoelectric conversion region of 1 mm×1 mm was prepared. The device sample was subjected to an annealing treatment at 150° C. for 210 minutes under a nitrogen (N₂) atmosphere. This experiment was set as Experimental Example 44.

In addition thereto, in Experimental Examples 45 to 68, preparations were performed using a method similar to that of Experimental Example 44. It is to be noted that compositions of the photoelectric conversion layers formed as films in Experimental Examples 34 to 68 are similar to those of the respective photoelectric conversion layers of Experimental Examples 20 to 43 prepared in Experiment 2.

The device samples prepared as Experimental Examples 44 to 68 were evaluated in terms of EQE and dark current characteristics using a semiconductor parameter analyzer. As for the EQE and the dark current characteristics, a current value (light current value) was measured in a case where an amount of light to irradiate the photoelectric conversion element from a light source via a filter was set to 1.62 μW/cm² and where a bias voltage to be applied between electrodes was set to −2.6 V, and a current value (dark current value) was measured in a case where the amount of light was set to 0 μW/cm²; the EQE and the dark current characteristics were each calculated from these values.

Further, in Experimental Examples 58 to 61, the EQE and the dark current characteristics were evaluated using a method similar to those described above, except that the wavelength of light to irradiate the device sample from the light source via the filter was set to 650 nm.

In addition, in Experimental Examples 44 to 68, heat resistance based on the dark current characteristics was evaluated. As for the evaluation of the heat resistance, the above-described device sample was subjected to an annealing treatment at 150° C. for 210 minutes under a nitrogen (N₂) atmosphere, followed by cooling to a room temperature, and then the dark current characteristics were evaluated by the above-described method to determine a relative value of the dark current characteristics after heating with respect to the dark current characteristics before the heating.

Table 4 summarizes a LUMO level of the first organic semiconductor material used in each of Experimental Examples 44 to 68 (Experimental Examples 19 to 43), a HOMO level of the second organic semiconductor material used therein, an energy gap ΔE₁₂ between the first organic semiconductor material and the second organic semiconductor material, and a position of each of first, second, and third peaks. Table 5 summarizes evaluation results of wavelength selectivity, heat resistance of absorptivity, EQE, and dark current characteristics in Experimental Examples 44 to 68 (Experimental Examples 19 to 43). It is to be noted that the numerical values listed in Table 5 are each a relative value with respect to the evaluation result of a device sample that is standardized by an absorption wavelength region targeted in each device sample. Specifically, in Experimental Examples 4 to 49 targeting absorption of blue light, relative values for which Experimental Example 44 is standardized are described. In Experimental Examples 51 to 57 and Experimental Examples 62 to 68 targeting absorption of green light, relative values for which Experimental Example 50 is standardized are described. In Experimental Examples 59 to 61 targeting absorption of red light, relative values for which the result of Experimental Example 58 is standardized are described.

TABLE 4

| | LUMO Level | LUMO Level | | | | |
|---|---|---|---|---|---|---|
| | (eV) | (eV) | | | | |
| | First Organic | Second Organic | | | | |
| | Semiconductor | Semiconductor | ΔE₁₂ | Peak Position (°) | | |
| | Material | Material | (eV) | First | Second | Third |
| Experimental Examples 19, 44 | 4.5 | 5.8 | 1.3 | 18.2 | 22.2 | 28.2 |
| Experimental Examples 20, 45 | 4.5 | 5.8 | 1.3 | 18.1 | 22.1 | 28.1 |
| Experimental Examples 21, 46 | 4.5 | 5.8 | 1.3 | 19.3 | 22.3 | 28.3 |
| Experimental Examples 22, 47 | 4.5 | 5.8 | 1.3 | 18.4 | 23.4 | 27.4 |
| Experimental Examples 23, 48 | 4.5 | 5.7 | 1.2 | 19.2 | 22.2 | 28.2 |
| Experimental Examples 24, 49 | 4.5 | 5.7 | 1.2 | 18.7 | 23.7 | 28.7 |
| Experimental Examples 25, 50 | 4.5 | 5.8 | 1.3 | 18.5 | 23.5 | 27.5 |
| Experimental Examples 26, 51 | 4.5 | 5.8 | 1.3 | 18.6 | 23.6 | 28.6 |
| Experimental Examples 27, 52 | 4.5 | 5.8 | 1.3 | 19.4 | 23.4 | 27.4 |
| Experimental Examples 28, 53, | 4.5 | 5.8 | 1.3 | 19.9 | 23.9 | 26.9 |
| Experimental Examples 29, 54 | 4.5 | 5.7 | 1.2 | 18.1 | 22.1 | 26.1 |
| Experimental Examples 30, 55 | 4.5 | 5.7 | 1.2 | 18.2 | 22.2 | 26.2 |
| Experimental Examples 31, 56 | 4.5 | 5.7 | 1.2 | 18.7 | 23.7 | 26.7 |
| Experimental Examples 32, 57 | 4.5 | 5.7 | 1.2 | 19.8 | 23.8 | 27.8 |
| Experimental Examples 33, 58 | 4.5 | 5.6 | 1.1 | 18.1 | 23.1 | 26.1 |
| Experimental Examples 34, 59 | 4.5 | 5.6 | 1.1 | 19.2 | 23.2 | 26.2 |
| Experimental Examples 35, 60 | 4.5 | 5.5 | 1.0 | 19.1 | 22.1 | 26.1 |
| Experimental Examples 36, 61 | 4.5 | 5.5 | 1.0 | 18.8 | 23.8 | 26.8 |
| Experimental Examples 37, 62 | 4.5 | 5.4 | 0.9 | 19.1 | 22.1 | 27.1 |
| Experimental Examples 38, 63 | 4.5 | 5.4 | 0.9 | 18.3 | 22.3 | 27.3 |
| Experimental Examples 39, 64 | 4.5 | 7.1 | 2.6 | 19.4 | 22.4 | 26.4 |
| Experimental Examples 40, 65 | 4.5 | 5.5 | 1 | 18.6 | 22.6 | 28.6 |
| Experimental Examples 41, 66 | 4.5 | 5.8 | 1.3 | — | — | — |
| Experimental Examples 42, 67 | 4.5 | 5.8 | 1.3 | 18.2 | 23.2 | 26.2 |
| Experimental Examples 43, 68 | 4.5 | 5.8 | 1.3 | 18.0 | 22.0 | 29.0 |

TABLE 5

| | | Heat | | | |
|---|---|---|---|---|---|
| | | Resistance | | Dark Current | |
| | Wavelength | of | | Character- | Heat |
| | Selectivity | Absorptivity | EQE | istics | Resistance |
| Experimental Examples 19, 44 | A | 1.0 | 1.0 | 1.0 | 1.0 |
| Experimental Examples 20, 45 | A | 0.9 | 1.0 | 1.1 | 1.0 |
| Experimental Examples 21, 46 | A | 0.9 | 1.0 | 1.0 | 0.9 |
| Experimental Examples 22, 47 | A | 1.0 | 1.2 | 1.2 | 1.0 |
| Experimental Examples 23, 48 | A | 1.0 | 1.0 | 1.0 | 1.0 |
| Experimental Examples 24, 49 | A | 0.9 | 0.9 | 1.0 | 1.0 |
| Experimental Examples 25, 50 | A | 1.0 | 1.0 | 1.0 | 1.0 |
| Experimental Examples 26, 51 | A | 1.0 | 1.0 | 1.1 | 1.0 |
| Experimental Examples 27, 52 | A | 1.0 | 1.0 | 1.0 | 1.0 |
| Experimental Examples 28, 53, | A | 1.0 | 1.0 | 0.9 | 1.0 |
| Experimental Examples 29, 54 | A | 0.9 | 0.9 | 1.0 | 0.9 |
| Experimental Examples 30, 55 | A | 0.9 | 0.9 | 1.1 | 0.9 |
| Experimental Examples 31, 56 | A | 1.0 | 0.9 | 1.0 | 1.0 |
| Experimental Examples 32, 57 | A | 1.0 | 0.9 | 1.2 | 1.0 |
| Experimental Examples 33, 58 | A | 1.0 | 1.0 | 1.0 | 0.9 |
| Experimental Examples 34, 59 | A | 1.0 | 1.0 | 1.2 | 0.9 |
| Experimental Examples 35, 60 | A | 0.9 | 0.9 | 0.9 | 1.0 |
| Experimental Examples 36, 61 | A | 1.0 | 0.9 | 1.2 | 1.0 |
| Experimental Examples 37, 62 | B | 1.0 | 0.8 | 1.0 | 1.0 |
| Experimental Examples 38, 63 | B | 1.0 | 0.7 | 1.2 | 1.0 |
| Experimental Examples 39, 64 | A | 1.0 | 0.0 | >10 | 1.0 |
| Experimental Examples 40, 65 | B | 1.0 | 0.6 | 1.1 | 1.0 |
| Experimental Examples 41, 66 | A | 0.7 | 1.0 | 2.0 | 0.5 |
| Experimental Examples 42, 67 | B | 0.9 | 1.0 | 1.0 | 1.0 |
| Experimental Examples 43, 68 | B | 0.9 | 1.0 | 1.0 | 1.0 |

Description has been given hereinabove referring to the first to fifth embodiments, Example, Application Examples, and Practical Application Examples; however, the content of the present disclosure is not limited to the foregoing embodiments and the like, and may be modified in a wide variety of ways. For example, the numbers and ratios of the organic photoelectric conversion section and the inorganic photoelectric conversion section are not limited. For example, no limitation is made to the structure in which the organic photoelectric conversion section and the inorganic photoelectric conversion section are stacked in the vertical direction; they may be arranged side by side along the substrate surface.

In addition, the foregoing embodiments, and the like exemplify the configuration of the back-illuminated solid-state imaging device; however, the content of the present disclosure is also applicable to a front-illuminated solid-state imaging device. Further, the photoelectric conversion element of the present disclosure need not include all of the components described in the foregoing embodiments, and may include any other layer, conversely.

Furthermore, the foregoing embodiments and the like exemplify the use of the photoelectric conversion element 1A or the like as the imaging element constituting the imaging device 100; however, the photoelectric conversion element 1A or the like of the present disclosure may be applied to a solar cell.

It is to be noted that the effects described herein are merely exemplary and are not limitative, and may further include other effects.

It is to be noted that the present disclosure may also have the following configurations. According to the present technology of the following configurations, the photoelectric conversion layer is provided between a first electrode and a second electrode, and includes three types of materials: the first organic semiconductor material; the second organic semiconductor material having a HOMO level which is deeper than a LUMO level of the first organic semiconductor material and has a difference of 1.0 eV or more and 2.0 eV or less from a HOMO level of the first organic semiconductor material; and the third organic semiconductor material having a crystalline property and having a linear absorption coefficient of 10000 cm⁻¹ or less in a visible light region and an optical absorption edge wavelength of 550 nm or less. This makes it possible to improve spectral characteristics, electric characteristics, and heat resistance.

(1)

A photoelectric conversion element including:
a first electrode;
a second electrode disposed to be opposed to the first electrode; and
an organic photoelectric conversion layer provided between the first electrode and the second electrode and including a first organic semiconductor material, a second organic semiconductor material, and a third organic semiconductor material, the second organic semiconductor material having a Highest Occupied Molecular Orbital (HOMO) level which is deeper than a Lowest Unoccupied Molecular Orbital (LUMO) level of the first organic semiconductor material and has a difference of 1.0 eV or more and 2.0 eV or less from the LUMO level of the first organic semiconductor material, the third organic semiconductor material having a crystalline property and having a linear absorption coefficient of 10000 cm⁻¹ or less in a visible light region and an optical absorption edge wavelength of 550 nm or less.
   (2)

The photoelectric conversion element according to (1), in which the first organic semiconductor material, the second organic semiconductor material, and the third organic semiconductor material each include a low-molecular compound having a molecular weight of 2000 or less.

(3)

The photoelectric conversion element according to (1) or (2), in which the first organic semiconductor material includes an electron-transporting material, the second organic semiconductor material includes a dye material, and the third organic semiconductor material includes a hole-transporting material.

(4)

The photoelectric conversion element according to any one of (1) to (3), in which the first organic semiconductor material includes fullerene or a derivative thereof.

(5)

The photoelectric conversion element according to any one of (1) to (4), in which the second organic semiconductor material includes a donor-acceptor dye material.

(6)

The photoelectric conversion element according to any one of (1) to (5), in which the second organic semiconductor material has local maximum absorption at a wavelength band of 380 nm or more and 750 nm or less.

(7)

The photoelectric conversion element according to any one of (1) to (6), in which the first electrode includes multiple electrodes independent of each other.

(8)

The photoelectric conversion element according to (7), in which the first electrode includes, as the multiple electrodes, a charge readout electrode and a charge accumulation electrode.

(9)

The photoelectric conversion element according to (7) or (8), in which a voltage is individually applied to each of the multiple electrodes.

(10)

An imaging device including multiple pixels each provided with one or multiple photoelectric conversion elements,
the photoelectric conversion element including
   a first electrode,
   a second electrode disposed to be opposed to the first electrode, and
   an organic photoelectric conversion layer provided between the first electrode and the second electrode and including a first organic semiconductor material, a second organic semiconductor material, and a third organic semiconductor material, the second organic semiconductor material having a Highest Occupied Molecular Orbital (HOMO) level which is deeper than a Lowest Unoccupied Molecular Orbital (LUMO) level of the first organic semiconductor material and has a difference of 1.0 eV or more and 2.0 eV or less from the LUMO level of the first organic semiconductor material, the third organic semiconductor material having a crystalline property and having a linear absorption coefficient of 10000 cm⁻¹ or less in a visible light region and an optical absorption edge wavelength of 550 nm or less.
      (11)

The imaging device according to (10), in which, in each of the pixels, one or multiple organic photoelectric conversion sections and one or multiple inorganic photoelectric conversion sections are stacked, the one or the multiple inorganic photoelectric conversion sections performing photoelectric conversion of a wavelength region different from the organic photoelectric conversion section.

(12)

The imaging device according to (11), in which
the inorganic photoelectric conversion section is formed to be embedded in a semiconductor substrate, and
the organic photoelectric conversion section is formed on a side of a first surface of the semiconductor substrate.
   (13)

The imaging device according to (12), in which
the semiconductor substrate has a second surface opposed to the first surface, and
a multilayer wiring layer is formed on a side of the second surface.

This application claims the benefit of Japanese Priority Patent Application JP2020-131137 filed with the Japan Patent Office on Jul. 31, 2020, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photoelectric conversion element comprising:
a first electrode;
a second electrode disposed to be opposed to the first electrode; and
an organic photoelectric conversion layer provided between the first electrode and the second electrode and including a first organic semiconductor material, a second organic semiconductor material, and a third organic semiconductor material, the second organic semiconductor material having a Highest Occupied Molecular Orbital (HOMO) level which is deeper than a Lowest Unoccupied Molecular Orbital (LUMO) level of the first organic semiconductor material and has a difference of 1.0 eV or more and 2.0 eV or less from the LUMO level of the first organic semiconductor material, the third organic semiconductor material having a crystalline property and having a linear absorption coefficient of 10000 cm⁻¹ or less in a visible light region and an optical absorption edge wavelength of 550 nm or less.

2. The photoelectric conversion element according to claim 1, wherein the first organic semiconductor material, the second organic semiconductor material, and the third organic semiconductor material each comprise a low-molecular compound having a molecular weight of 2000 or less.

3. The photoelectric conversion element according to claim 1, wherein
the first organic semiconductor material comprises an electron-transporting material,
the second organic semiconductor material comprises a dye material, and
the third organic semiconductor material comprises a hole-transporting material.

4. The photoelectric conversion element according to claim 1, wherein the first organic semiconductor material comprises fullerene or a derivative thereof.

5. The photoelectric conversion element according to claim 1, wherein the second organic semiconductor material comprises a donor-acceptor dye material.

6. The photoelectric conversion element according to claim 1, wherein the second organic semiconductor material has local maximum absorption at a wavelength band of 380 nm or more and 750 nm or less.

7. The photoelectric conversion element according to claim 1, wherein the first electrode includes multiple electrodes independent of each other.

8. The photoelectric conversion element according to claim 7, wherein the first electrode includes, as the multiple electrodes, a charge readout electrode and a charge accumulation electrode.

9. The photoelectric conversion element according to claim 7, wherein a voltage is individually applied to each of the multiple electrodes.

10. An imaging device comprising multiple pixels each provided with one or multiple photoelectric conversion elements,
the photoelectric conversion element including
a first electrode,
a second electrode disposed to be opposed to the first electrode, and
an organic photoelectric conversion layer provided between the first electrode and the second electrode and including a first organic semiconductor material, a second organic semiconductor material, and a third organic semiconductor material, the second organic semiconductor material having a Highest Occupied Molecular Orbital (HOMO) level which is deeper than a Lowest Unoccupied Molecular Orbital (LUMO) level of the first organic semiconductor material and has a difference of 1.0 eV or more and 2.0 eV or less from the LUMO level of the first organic semiconductor material, the third organic semiconductor material having a crystalline property and having a linear absorption coefficient of 10000 cm⁻¹ or less in a visible light region and an optical absorption edge wavelength of 550 nm or less.

11. The imaging device according to claim 10, wherein, in each of the pixels, one or multiple organic photoelectric conversion sections and one or multiple inorganic photoelectric conversion sections are stacked, the one or the multiple inorganic photoelectric conversion sections performing photoelectric conversion of a wavelength region different from the organic photoelectric conversion section.

12. The imaging device according to claim 11, wherein
the inorganic photoelectric conversion section is formed to be embedded in a semiconductor substrate, and
the organic photoelectric conversion section is formed on a side of a first surface of the semiconductor substrate.

13. The imaging device according to claim 12, wherein
the semiconductor substrate has a second surface opposed to the first surface, and
a multilayer wiring layer is formed on a side of the second surface.
